(19) United States
(12) Patent Application Publication
(10) Pub. No.: US 2012/0085396 A1
(43) Pub. Date: Apr. 12, 2012

(54) PHOTOELECTRIC CONVERSION ELEMENT, METHOD OF MANUFACUTRING PHOTOELECTRIC CONVERSION ELEMENT, ELECTROLYTE LAYER FOR PHOTOELECTRIC CONVERSION ELEMENT, AND ELECTRONIC APPARATUS

(75) Inventors: Ryohei Tsuda, Kanagawa (JP); Kiyoshi Kumagae, Kanagawa (JP)

(73) Assignee: Sony Corporation, Tokyo (JP)

(21) Appl. No.: 13/251,465

(22) Filed: Oct. 3, 2011

(30) Foreign Application Priority Data
Oct. 12, 2010 (JP) 2010-229333

(51) Int. Cl. H01L 31/02; H01L 31/18; H01L 31/0224

(52) U.S. Cl. 136/254; 438/57; 257/E31.001

(57) ABSTRACT

A photoelectric conversion element has a structure in which an electrolyte layer composed of a porous film containing an electrolyte solution is provided between a porous photoelectrode and a counter electrode.

### BACKGROUND

The present disclosure relates to a photoelectric conversion element, a method of manufacturing a photoelectric conversion element, an electrolyte layer for a photoelectric conversion element, and an electronic apparatus. For example, the present disclosure relates to a photoelectric conversion element which is suitable for use in a dye-sensitized solar cell, a method of manufacturing the photoelectric conversion element, and an electronic apparatus using the photoelectric conversion element.

A solar cell as a photoelectric conversion element operable to convert sunlight into electrical energy uses the sunlight as a source of energy. Therefore, the solar cell has extremely little influence on global environments and, hence, is expected to be used more widely.

Of the solar cells, those which have been mainly used are crystal-silicon solar cells, using single crystal silicon or polycryatalline silicon, and amorphous-silicon solar cells.

On the other hand, the dye-sensitized solar cell proposed by Grätzel et al in 1991 has been paid attention to since it can exhibit a high photoelectric conversion efficiency and, unlike silicon solar cells according to the related art, it can be manufactured at low cost without needing a large-scale equipment (see, for example, Nature, 353, pp. 737-740, 1991).

The dye-sensitized solar cell, in general, has a structure in which a porous photoelectrode formed of oxide titanium or the like with a photosensitizing dye bonded thereto and a counter electrode formed of platinum or the like are disposed to face each other, and the space between these electrodes is filled with an electrolyte layer having an electrolyte solution. As the electrolyte solution, solutions prepared by dissolving in a solvent an electrolyte including oxidation-reduction species such as iodine and iodide ion are frequently used.

The dye-sensitized solar cells according to the related art are generally manufactured by the method as shown in FIGS. 29A to 29E.

As shown in FIG. 29A, first, a porous photoelectrode 102 is formed on a transparent conductive substrate 101.

Next, as shown in FIG. 29B, a counter electrode 103 is prepared, and the porous photoelectrode 102 on the transparent conductive substrate 101 and the counter electrode 103 are disposed to face each other. Then, a sealing material 104 is formed at the outer peripheral portions of the transparent conductive substrate 101 and the counter electrode 103, to form a space in which an electrolyte layer is to be sealed.

Subsequently, as shown in FIG. 29C, an electrolyte solution is poured through a liquid pouring hole 103a preliminarily formed in the counter electrode 103, to form the electrolyte layer 105.

Next, as shown in FIG. 29D, the portion of the electrolyte solution flowing over to the outside from the liquid pouring hole 103a of the counter electrode 103 is wiped away.

Thereafter, as shown in FIG. 29E, a sealing plate 106 is adhered to the upper surface of the counter electrode 103 so as to close the liquid pouring hole 103a.

In this way, the desired dye-sensitized solar cell is manufactured.

### SUMMARY

The dye-sensitized solar cell according to the related art, however, have had a problem in that when the dye-sensitized solar cell is broken for some reason, the electrolyte solution may leak to the exterior from the electrolyte layer 105 sealed between the porous photoelectrode 102 and the counter electrode 103.

Thus, there is a need for a photoelectric conversion element such as a dye-sensitized solar cell in which leakage of an electrolyte solution can be prevented from occurring upon breakage of the element.

Also, there is a need for a method of manufacturing a photoelectric conversion element by which such an excellent photoelectric conversion element as above-mentioned can be manufactured easily.

Besides, there is a need for an electrolyte layer for a photoelectric conversion element that is suitable for use in manufacturing such an excellent photoelectric conversion element as above-mentioned.

Further, there is a need for a high-performance electronic apparatus in which such an excellent photoelectric conversion element as above-mentioned is used.

According to an embodiment of the present disclosure, there is provided

a photoelectric conversion element having a structure in which an electrolyte layer composed of a porous film containing an electrolyte solution is provided between a porous photoelectrode and a counter electrode.

According to another embodiment of the present disclosure, there is provided

a method of manufacturing a photoelectric conversion element, including:

disposing a porous film on one of a porous photoelectrode and a counter electrode; and

disposing the other of the porous photoelectrode and the counter electrode on the porous film.

According to a further embodiment of the present disclosure, there is provided

an electrolyte layer for a photoelectric conversion element, including a porous film which contains an electrolyte solution.

According to yet another embodiment of the present disclosure, there is provided an electronic apparatus including

a photoelectric conversion element, wherein the photoelectric conversion element has a structure in which an electrolyte layer having a porous film containing an electrolyte solution is provided between a porous photoelectrode and a counter electrode.

In the present disclosure, the porous film to be used to constitute the electrolyte layer may be one of various porous films, and its structure, material and the like are selected according to the necessity. Specifically, as the porous film, an insulating one is used. The insulating porous film may be formed of an insulating material, or may be one obtained, for example, by a method in which surfaces of voids of a porous film formed of a conductive material are converted into an insulating material or the surfaces of the voids are coated with an insulating film. The porous film may be formed from an organic material or an inorganic material. Preferably, one of various non-woven fabrics is used as the porous film. Non-limitative examples of the material which can be used for forming the non-woven fabric include organic polymer compounds such as polyolefins, polyesters, and cellulose. The porosity of the porous film is selected according to the necessity. The porosity of the porous film in the state of being provided between the porous photoelectrode and the counter electrode (the actual porosity) is preferably not less than 50%. From the viewpoint of securing a high photoelectric conversion efficiency, the actual porosity is preferably selected to be not less than 80% and less than 100%.

The electrolyte solution contained in the porous film constituting the electrolyte layer is, from the viewpoint of preventing volatilization thereof, preferably a lowly volatile electrolyte solution, for example, an ionic liquid electrolyte solution in which an ionic liquid is used as solvent. The ionic liquid may be one of known ones, and is selected according to the necessity.

In the method of manufacturing a photoelectric conversion element according to an embodiment of the present disclosure, the porous film may or may not contain an electrolyte solution. Where a porous film containing an electrolyte solution is used, the porous film containing the electrolyte solution constitutes the electrolyte layer. Where a porous film not containing any electrolyte solution is used, an electrolyte solution can be poured into the porous film in a later step. For example, an electrolyte solution can be poured into the porous film in a state in which the porous film is sandwiched between the porous photoelectrode and the counter electrode. Typically, the porous film is disposed on the porous photoelectrode, and thereafter the counter electrode is disposed on the porous film, but this is not limitative. The method of manufacturing a photoelectric conversion element according to an embodiment of the present disclosure further includes, if necessary, compressing the porous film after the porous film containing the electrolyte solution is disposed on the porous photoelectrode and before the counter electrode is disposed on the porous film; in this case, the compression is typically carried out by pressing the porous film in a direction perpendicular to the film plane. This ensures that when the porous film is compressed and its volume is thereby reduced, the electrolyte solution contained in the voids of the porous film is pressed out, to permeate the porous photoelectrode. Consequently, a state in which the electrolyte solution is present throughout the range from the porous film to the porous photoelectrode can be easily realized.

The photoelectric conversion element, typically, is a dye-sensitized photoelectric conversion element in which a photosensitizing dye is bonded to (or adsorbed on) a porous photoelectrode. In this case, the method of manufacturing the photoelectric conversion element, typically, further includes bonding the photosensitizing dye to the porous photoelectrode. The porous photoelectrode includes particulates having a semiconductor. The semiconductor preferably includes titanium oxide (TiO₂), particularly, anatase type TiO₂.

As the porous photoelectrode, one having particulates of a so-called core-shell structure may be used; in this case, the photosensitizing dye may not necessarily be bonded to the porous photoelectrode. As the porous photoelectrode, preferably, one having particulates each of which includes a core having a metal and a shell having a metallic oxide surrounding the core is used. Use of such a porous photoelectrode ensures that, in the case where the electrolyte layer having the porous film containing the electrolyte solution is provided between the porous photoelectrode and the counter electrode, the electrolyte of the electrolyte solution does not make contact with the metal core of the metal/metallic oxide particulates, so that the porous photoelectrode can be prevented from being dissolved by the electrolyte. Therefore, as the metal constituting the cores of the metal/metallic oxide particulates, there can be used the metals which have a high surface plasmon resonance effect and which have been difficult to use in the related art, such as gold (Au), silver (Ag), and copper (Cu). This enables the surface plasmon resonance effect to be sufficiently obtained in the photoelectric conversion. In addition, iodine electrolytes can be used as the electrolyte of the electrolyte solution. Platinum (Pt), palladium (Pd) and the like can also be used as the metal constituting the cores of the metal/metallic oxide particulates. As the metallic oxide constituting the shells of the metal/metallic oxide particulates, a metallic oxide which is insoluble in the electrolyte used is used. The metallic oxide to be used is selected according to the necessity. As the metallic oxide, preferably, at least one metallic oxide selected from the group consisting of titanium oxide (TiO₂), tin oxide (SnO₂), niobium oxide (Nb₂O₅) and zinc oxide (ZnO) is used. The just-mentioned metallic oxides, however, are non-limitative examples. For instance, other metallic oxides such as tungsten oxide (WO₃) and strontium titanate (SrTiO₃) can also be used. The particle diameter of the particulates is selected suitably, and is preferably in the range of 1 to 500 nm. Besides, the particle diameter of the cores of the particulates is also selected suitably, and is preferably in the range of 1 to 200 nm.

The photoelectric conversion element, most typically, is configured as a solar cell. However, the photoelectric conversion element may also be other than a solar cell; for example, it may be a photosensor or the like.

The electronic apparatus, basically, may be any of various electronic apparatuses, which include both portable ones and stationary ones. Specific examples of the electronic apparatus include portable phones, mobile apparatuses, robots, personal computers, on-vehicle apparatuses, and various home electronics. In this case, the photoelectric conversion element is, for example, a solar cell for use as power supply in these electronic apparatuses.

By the way, the electrolyte solution generally contains an additive added thereto for preventing reverse movement of electrons from the porous photoelectrode into the electrolyte solution. As the additive, the best known is 4-tert-butylpyridine (TBP). The number of the kinds of additives for the electrolyte solution has been limited, the choice of the additives has been extremely narrow, and the degree of freedom in designing the electrolyte solution has been low. In view of this, the present inventors earnestly made experimental and theoretical studies with the intention of broaden the choice of the additives. As a result of their studies, it has been found out that there are many additives which, when added to the electrolyte solution, can give better characteristics than those offered by 4-tert-butylpyridine generally used in the past.

Specifically, it has been concluded that better properties than those obtained by use of 4-tert-butylpyridine can be obtained by use of an additive which has a pKₐ in the range of 6.04≦pKₐ≦7.3. For putting this into effect, an additive having a pKₐ in the range of 6.04≦pKₐ≦7.3 is added to the electrolyte solution and/or an additive having a pKₐ in the range of 6.04≦pKₐ≦7.3 is adsorbed on that surface of at least one of the porous photoelectrode and the counter electrode which faces the electrolyte solution. This makes it possible to obtain a photoelectric conversion element in which the choice of additives to an electrolyte solution is broad and better characteristics can be obtained, as compared with the case where 4-tert-butylpyridine is used as an additive.

The additive which is added to the electrolyte solution or is adsorbed on the surface of at least one of the porous photoelectrode and the counter electrode may fundamentally be any substance, insofar as the substance has a pKₐ in the range of 6.04≦pKₐ≦7.3, where Ka is the equilibrium constant in dissociation equilibrium of a conjugate acid in water. Typical examples of this additive include pyridine additives and those additives which have a heterocyclic ring. Specific examples of the pyridine additives include 2-aminopyridine (2-NH2-Py), 4-methoxypyridine (4-MeO-Py), and 4-ethylpyridine (4-Et-Py), which are not limitative. On the other hand, specific examples of the additives having a heterocyclic ring include N-methylimidazole (MIm), 2,4-lutidine (24-Lu), 2,5-lutidine (25-Lu), 2,6-lutidine (26-Lu), 3,4-lutidine (34-Lu), and 3,5-lutidine (35-Lu), which are not limitative. The additive, for example, has at least one selected from the group consisting of 2-aminopyridine, 4-methoxypyridine, 4-ethylpyridine, N-methylimidazole, 2,4-lutidine, 2,5-lutidine, 2,6-lutidine, 3,4-lutidine, and 3,5-lutidine. Incidentally, compounds having in the molecule thereof a structure of a pyridine or heterocyclic compound with a pKₐ in the range of 6.04≦pKₐ≦7.3 are expected to be able to produce the same effect as that of the above-mentioned additives with a pKₐ in the range of 6.04≦pKₐ≦7.3.

In order to adsorb the additive on a surface of at least one of the porous photoelectrode and the counter electrode (on the interface between the porous photoelectrode or the counter electrode and the electrolyte layer, after the electrolyte layer is provided between the porous photoelectrode and the counter electrode), it suffices for the additive to be brought into contact with the surface of the porous photoelectrode or the counter electrode by use of the additive itself, an organic solvent containing the additive, an electrolyte solution containing the additive, or the like, before the electrolyte layer is provided between the porous photoelectrode and the counter electrode. Specifically, it suffices, for example, that the porous photoelectrode or the counter electrode is immersed in an organic solvent containing the additive or that an organic solvent containing the additive is sprayed onto the surface of the porous photoelectrode or the counter electrode.

In the case of using the above-mentioned additive, the molecular weight of the solvent in the electrolyte solution is preferably not less than 47.36. Non-limitative examples of such a solvent include nitrile solvents such as 3-methoxypropionitrile (MPN), methoxyacetonitrile (MAN), acetonitrile (AN), valeronitrile (VN), etc., carbonate solvents such as ethylene carbonate, propylene carbonate, etc., sulfone solvents such as sulfolane, etc., lactone solvents such as γ-butyrolactone, etc., which may be used either singly or as a mixture of two or more of them.

Meanwhile, as solvent of the electrolyte solution in a dye-sensitized solar cell, volatile organic solvents such as acetonitrile have been used heretofore. Such a dye-sensitized solar cell, however, has had a problem in that when the electrolyte solution is exposed to the atmosphere due to breakage of the solar cell, transpiration of the electrolyte would occur, leading to a failure of the solar cell. In order to solve this problem, in recent years, difficultly volatile molten salts called ionic liquids have come to be used, instead of volatile organic solvents, as solvent of the electrolyte solution of the dye-sensitized solar cell (see, for example, Inorg. Chem., 1996, 35, 1168-1178, and J. Chem. Phys., 124, 184902 (2006)). As a result, the problem of volatilization of the electrolyte solution in dye-sensitized solar cells is being improved. However, ionic liquids are much higher in viscosity coefficient than the organic solvents which have been used in the related art; therefore, photoelectric conversion characteristics of the dye-sensitized solar cells using the ionic liquids are actually poorer than those of the dye-sensitized solar cells according to the related art. Accordingly, there is a need for a dye-sensitized solar cell in which volatilization of the electrolyte solution can be restrained and excellent photoelectric conversion characteristics can be obtained. In order to meet the need, the present inventors made intensive and extensive studies. In the process of their studies, particularly in search for an improving measure for the problem of deterioration of photoelectric conversion characteristics in using an ionic liquid as solvent of the electrolyte solution, they made an attempt to dilute ionic liquids with organic solvents, while expecting that no improving effect would be obtainable by the dilution. The results were as expected. Specifically, when a solvent obtained by diluting an ionic liquid with a volatile organic solvent is used for the electrolyte solution, photoelectric conversion characteristics are enhanced due to lowering in the viscosity coefficient of the electrolyte solution, but there still remains the problem of volatilization of the organic solvent. For verifying the foregoing more securely, the present inventors made further attempts to dilute the inorganic liquids by use of various organic solvents. As a result, they found out that specific combinations of ionic liquid with organic solvent makes it possible to effectively restrain the volatilization of the electrolyte, without degrading the photoelectric conversion characteristics. This was a finding beyond expectation. Based on the unexpected finding, the present inventors advanced experimental and theoretical investigations. As a result, they reached a conclusion that it is effective to contain in the solvent of the electrolyte solution an ionic liquid having an electron-acceptive functional group and an organic solvent having an electron-donative functional group. In this case, in the solvent of the electrolyte solution, a hydrogen bond is formed between the electron-acceptive functional group of the ionic liquid and the electron-donative functional group of the organic solvent. Since the molecule of the ionic liquid and the molecule of the organic solvent are coupled together through the hydrogen bond, it is possible to restrain volatilization of the organic liquid and, hence, of the electrolyte solution, as compared with the case where the organic solvent is used by itself. Besides, since the solvent of the electrolyte solution contains the organic solvent in addition to the ionic liquid, the viscosity coefficient of the electrolyte solution can be lowered and deterioration of photoelectric conversion characteristics can be prevented, as compared with the case where only the ionic liquid is used as the solvent. Consequently, volatilization of the electrolyte solution can be restrained, and excellent photoelectric conversion characteristics can be obtained.

The term “ionic liquid” used here include not only salts which show liquid state at 100° C. (inclusive of salts which can be in liquid state at room temperature due to supercooling, notwithstanding their melting points or glass transition temperatures of not less than 100° C.) but also other salts which are brought into liquid state while forming one or more phases upon addition of a solvent thereto. The ionic liquid may basically be any ionic liquid that has an electron-acceptive functional group, and the organic solvent may fundamentally be any organic solvent that has an electron-donative functional group. The ionic liquid, typically, is one whose cation has an electron-acceptive functional group. The ionic liquid, preferably, includes an organic cation which has an aromatic amine cation having a quaternary nitrogen atom and which has a hydrogen atom in an aromatic ring, and an anion (inclusive of not only organic anions but also inorganic anions such as AlCl₄⁻ and FeCl₄⁻) which has a van der Waals volume of not less than 76 Å³, the combination being non-limitative. The content of the ionic liquid in the solvent is selected according to the necessity; preferably, the ionic liquid is contained in a proportion of not less than 15 wt % and less than 100 wt %, based on the solvent which includes the ionic liquid and the organic solvent. The electron-donative functional group of the organic solvent, preferably, is an ether group or an amino group, which is a non-limitative example.

As above-mentioned, the solvent of the electrolyte solution contains an ionic liquid having an electron-acceptive functional group and an organic solvent having an electron-donative functional group, and this produces the following effect. In the solvent of the electrolyte solution, a hydrogen bond is formed between the electron-acceptive functional group of the ionic liquid and the electron-donative functional group of the organic solvent. Since the molecule of the ionic liquid and the molecule of the organic solvent are coupled together through the hydrogen bond, volatilization of the organic liquid and, hence, of the electrolyte solution can be restrained, as compared with the case where the organic solvent is used alone. Besides, since the solvent of the electrolyte solution contains the organic solvent in addition to the ionic liquid, the viscosity coefficient of the electrolyte solution can be lowered and deterioration of photoelectric conversion characteristics can be prevented, as compared with the case where the ionic liquid alone is used as solvent. Accordingly, it is possible to realize a photoelectric conversion element in which volatilization of the electrolyte solution can be restrained and excellent photoelectric conversion characteristics can be obtained.

According to the embodiments of the present disclosure, the electrolyte layer has a porous film containing an electrolyte solution, and the electrolyte layer is in a solid state; therefore, leakage of the electrolyte solution can be prevented from occurring upon breakage of the photoelectric conversion element. In addition, incident light transmitted through the porous photoelectrode to enter the element is scattered by the porous film constituting the electrolyte layer, to be again incident on the porous photoelectrode, so that efficiency of trapping the incident light by the porous photoelectrode is enhanced. This makes it possible to realize a photoelectric conversion element which is high in short-circuit current density and photoelectric conversion efficiency. Besides, since the electrolyte layer can be formed by use of the porous film containing the electrolyte solution, the electrolyte solution can substantially be handled as a film, so that the electrolyte solution can be handled extremely easily. This makes it possible to easily realize a photoelectric conversion element which has excellent characteristics. Consequently, by use of the excellent photoelectric conversion element, it is possible to realize a high-performance electronic apparatus and the like.

### BRIEF DESCRIPTION OF THE DRAWINGS

FIG. 1 is a sectional view showing a dye-sensitized photoelectric conversion element according to a first embodiment of the present disclosure;

FIGS. 2A to 2C are sectional views illustrating a method of manufacturing the dye-sensitized photoelectric conversion element according to the first embodiment;

FIG. 3 is a diagram for illustrating the operation principle in the case of using Z907 and Dye A as photosensitizing dye in the dye-sensitized photoelectric conversion element according to the first embodiment;

FIG. 4 is a diagram showing the structural formula of Z907;

FIG. 5 is a diagram showing the results of measurement of IPCE spectrum of a dye-sensitized photoelectric conversion element in which Z907 is solely bonded to a porous photoelectrode;

FIG. 6 is a diagram showing the structural formula of Dye A;

FIG. 7 is a diagram showing the results of measurement of IPCE spectrum of a dye-sensitized photoelectric conversion element in which Dye A is solely bonded to a porous photoelectrode;

FIG. 8 is a diagram showing the structural formula of Z991;

FIG. 9 is a diagram showing the results of measurement of photoelectric conversion characteristics for dye-sensitized photoelectric conversion elements obtained in Examples 1 to 5;

FIG. 10 is a diagram showing the results of measurement of photoelectric conversion characteristics for dye-sensitized photoelectric conversion elements obtained in Examples 6 and 7;

FIG. 11 is a diagram showing the relationship between actual porosity of a porous film constituting an electrolyte layer and normalized photoelectric conversion efficiency, for the dye-sensitized photoelectric conversion elements obtained in Examples 1 to 7;

FIG. 12 is a diagram showing the results of measurement of IPCE spectrum of dye-sensitized photoelectric conversion elements in which Z991 is solely bonded to a porous photoelectrode;

FIGS. 13A and 13B are diagrams showing the manner of scattering of light by an electrolyte layer in the dye-sensitized photoelectric conversion element according to the first embodiment of the present disclosure, in comparison with a related-art dye-sensitized photoelectric conversion element in which an electrolyte layer having only an electrolyte solution is used;

FIGS. 14A to 14C are sectional views showing a method of manufacturing a dye-sensitized photoelectric conversion element according to a second embodiment of the present disclosure;

FIGS. 15A and 15B are sectional views showing the method of manufacturing the dye-sensitized photoelectric conversion element according to the second embodiment;

FIG. 16 is a diagram showing the relationship between pKₐ of various additives and photoelectric conversion efficiency of dye-sensitized photoelectric conversion elements in which the additives are added to the electrolyte solution, respectively;

FIG. 17 is a diagram showing the relationship between pKₐ of various additives to be added to the electrolyte solution and internal resistance of the dye-sensitized photoelectric conversion elements in which the additives are added to the electrolyte solution, respectively;

FIG. 18 is a diagram showing dependence of the effect of an additive on the kind of solvent of the electrolyte solution;

FIG. 19 is a diagram showing the results of TG-DTA measurement for various solvents;

FIG. 20 is a diagram showing the results of TG-DTA measurement for various solvents;

FIG. 21 is a diagram showing the results of TG-DTA measurement for various solvents;

FIG. 22 is a diagram showing the results of TG-DTA measurement for various solvents;

FIG. 23 is a diagram showing the results of acceleration test for dye-sensitized photoelectric conversion elements according to a fourth embodiment of the present disclosure;

FIG. 24 is a diagram showing the measurement results of the relationship between the content of EMImTCB in an EMImTCB-triglyme mixed solvent and evaporation rate lowering ratio;

FIG. 25 is a diagram showing the measurement results of the relationship between van der Waals volume and evaporation rate lowering ratio for various ionic liquids;

FIG. 26 is a diagram showing the manner in which a hydrogen bond is formed between an ionic liquid having an electron-acceptive functional group and an organic solvent having an electron-donative functional group;

FIG. 27 is a diagram showing the manner in which a plurality of hydrogen bonds are formed between an ionic liquid having electron-acceptive functional groups and an organic solvents having a plurality of electron-donative functional groups;

FIG. 28 is a sectional view showing the structure of a metal/metallic oxide particulate constituting a porous photoelectrode in a dye-sensitized photoelectric conversion element according to a fifth embodiment of the present disclosure; and

FIGS. 29A to 29E are sectional views showing a method of manufacturing a dye-sensitized photoelectric conversion element according to the related art.

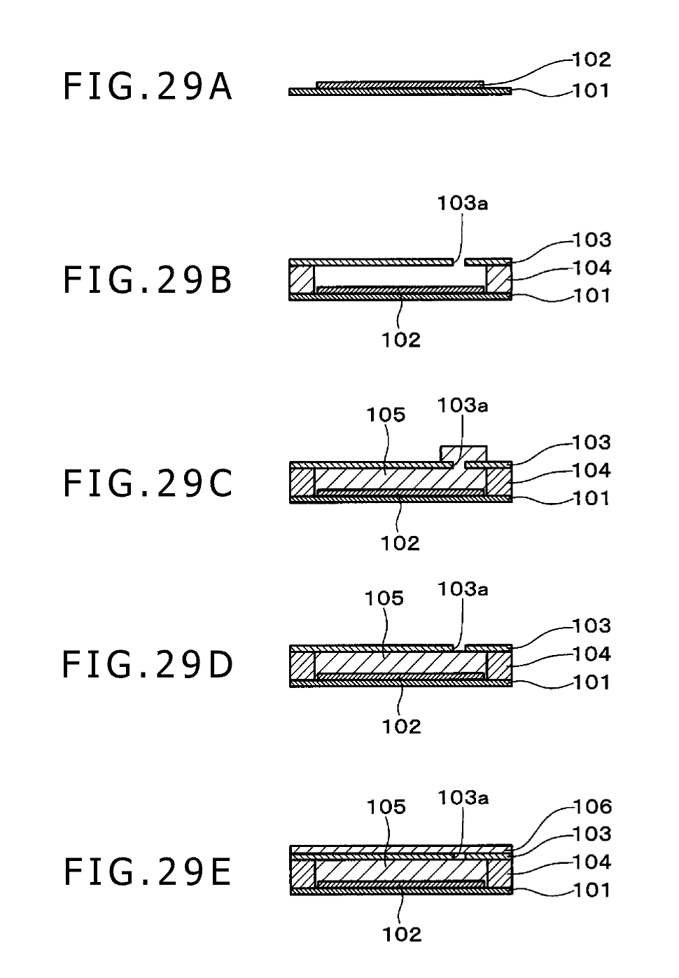

### DETAILED DESCRIPTION OF THE PREFERRED EMBODIMENTS

Now, modes for carrying out the present disclosure (the modes will hereinafter be referred to as “embodiments”) will be described below. The description will be made in the following order.

1. First Embodiment (Dye-sensitized photoelectric conversion element and manufacturing method therefor)
2. Second Embodiment (Dye-sensitized photoelectric conversion element and manufacturing method therefor)
3. Third Embodiment (Dye-sensitized photoelectric conversion element and manufacturing method therefor)
4. Fourth Embodiment (Dye-sensitized photoelectric conversion element and manufacturing method therefor)
5. Fifth Embodiment (Dye-sensitized photoelectric conversion element and manufacturing method therefor)
6. Sixth Embodiment (Photoelectric conversion element and manufacturing method therefor)

### 1. First Embodiment

### Dye-Sensitized Photoelectric Conversion Element

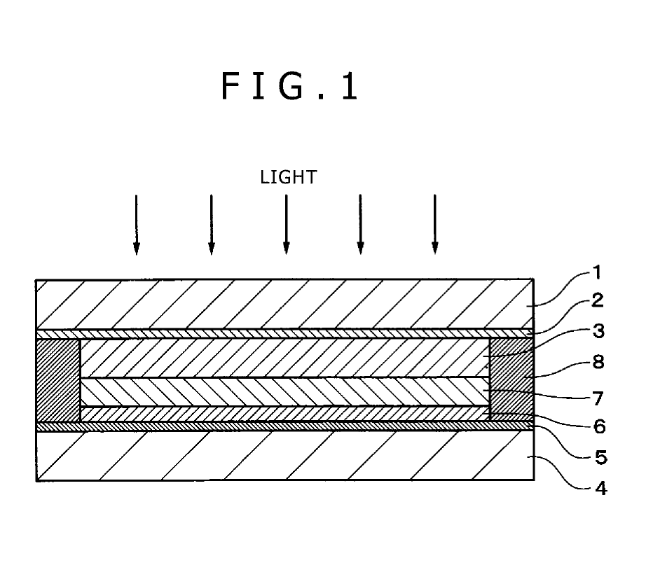

FIG. 1 is a major part sectional view showing a dye-sensitized photoelectric conversion element according to a first embodiment.

As shown in FIG. 1, in this dye-sensitized photoelectric conversion element, a transparent electrode 2 is provided on one principal surface of a transparent substrate 1, and a porous photoelectrode 3 having a predetermined plane shape which is smaller than the transparent electrode 2 is provided on the transparent electrode 2. One or more photosensitizing dyes (not shown) are bonded to the porous photoelectrode 3. On the other hand, a conductive layer 5 is provided on one principal surface of a counter substrate 4, and a counter electrode 6 is provided on the conductive layer 5. The counter electrode 6 has the same plane shape as that of the porous photoelectrode 3. An electrolyte layer 7 having a porous film containing an electrolyte solution or impregnated with an electrolyte solution is provided between the porous photoelectrode 3 on the transparent substrate 1 and the counter electrode 6 on the counter substrate 4. In addition, outer peripheral portions of the transparent substrate 1 and the counter substrate 4 are sealed with a sealing material 8. The sealing material 8 is in contact with the transparent electrode 2 and the conductive layer 5. In this instance, the transparent electrode 2 may be formed in the same plane shape as the porous photoelectrode 3 so that the sealing material 8 makes contact with the transparent substrate 1, or the counter electrode 6 may be formed over the whole area of the conductive layer 5 so that the sealing material 8 makes contact with the counter electrode 6.

As the porous photoelectrode 3, typically, a porous semiconductor layer obtained by sintering semiconductor particulates is used. A dye-sensitizing is adsorbed on the surfaces of the semiconductor particulates. Examples of the material which can be used for the semiconductor particulates include elemental semiconductors represented by silicon, compound semiconductors, and semiconductors having a perovskite structure. These semiconductors are preferably n-type semiconductors in which conduction band electrons become carriers under excitation with light, producing an anode current. Specific examples of the semiconductors are such semiconductors as titanium oxide (TiO₂), zinc oxide (ZnO), tungsten oxide (WO₃), niobium oxide (Nb₂O₅), strontium titanate (SrTiO₃), and tin oxide (SnO₂). Among these semiconductors, preferred is TiO₂, particularly, anatase-type TiO₂. It is to be noted here, however, that these semiconductors are not limitative, and a mixture or composite material of two or more of the semiconductors can be used according to the necessity. Besides, the form of the semiconductor particulates may be any of granular form, tubular form, rod-like form, etc.

While the particle diameter of the semiconductor particulates is not particularly limited, it is preferably 1 to 200 nm, particularly 5 to 100 nm, in terms of average particle diameter of primary particles. In addition, by admixing the semiconductor particulates with semiconductor particles greater in size than the semiconductor particulates, the incident light can be scattered by the semiconductor particles, thereby enhancing quantum yield. In this case, the average size of the semiconductor particles mixed into the semiconductor particulates is preferably 20 to 500 nm, which is not limitative.

In order to enable as large an amount as possible of a photosensitizing dye to be bonded to the porous photoelectrode 3, the porous photoelectrode 3 preferably has a large actual surface area. The actual surface area here means the total area inclusive of the particulate surfaces facing the pores in the inside of the porous semiconductor layer having the semiconductor particulates. In view of this, the actual surface area in the state in which the porous photoelectrode 3 is formed on the transparent electrode 2 is preferably not less than ten times, more preferably not less than 100 times, the outside surface area (projection area) of the porous photoelectrode 3. The ratio of the actual surface area to the outside surface area (projection area) does not have a particular upper limit, but, ordinarily, the ratio is up to about 1000.

In general, as the thickness of the porous photoelectrode 3 increases and the number of the semiconductor particulates contained in the porous photoelectrode 3 per unit projection area increases, the actual surface area increases and the amount of the photosensitizing dye which can be held in unit projection area increases, resulting in an increase in light absorptivity. On the other hand, as the thickness of the porous photoelectrode 3 increases, the distance by which the electrons transferred from the photosensitizing dye to the porous photoelectrode 3 diffuse until they reach the transparent electrode 2 increases, so that the loss of electrons due to charge coupling in the porous photoelectrode 3 is also increased. Therefore, there is a preferable thickness for the porous photoelectrode 3. The preferable thickness is generally 0.1 to 100 μm, more preferably 1 to 50 μm, and particularly preferably 3 to 30 μm.

As the porous film constituting the electrolyte layer 7, for example, various non-woven fabrics having organic polymers may be used. Table 1 below show specific, non-limitative examples of the non-woven fabric which can be used as the porous film.

TABLE 1

| | | | | Actual |
|---|---|---|---|---|
| Non-woven | Blank | Porosity | Thickness | Porosity |
| Fabric | Material | (%) | (μm) | (%) |
| Example 1 | polyolefin | 71.4 | 31.2 | 50 |
| Example 2 | polyolefin | 70.7 | 30 | 51 |
| Example 3 | polyolefin | 70.5 | 44 | 28 |
| Example 4 | polyester | 79 | 28 | 67 |
| Example 5 | cellulose | 72.8 | 29.8 | 55 |
| Example 6 | polyester | 78.3 | 32 | 61 |
| Example 7 | polyester | 82.7 | 22 | 79 |
| Comparative | electrolyte | 100 | | 100 |
| Example 1 | solution | | | |
| | alone | | | |

The electrolyte solution contained in the porous film constituting the electrolyte layer 7 may be, for example, a solution containing an oxidation-reduction system (redox pair). The oxidation-reduction system is not specifically restricted insofar as it includes substances which have appropriate oxidation-reduction potentials. Specifically, as the oxidation-reduction system, for example, a combination of iodine (I₂) with an iodide salt of a metal or organic substance, a combination of bromine (Br₂) with a bromide salt of a metal or organic substance, or the like is used. In this case, examples of the cation constituting the metallic salt include lithium (Li⁺), sodium (Na⁺), potassium (K⁺), cesium (Cs⁺), magnesium (Mg²⁺), and calcium (Ca²⁺). Besides, examples of the cation constituting the organic salt include quaternary ammonium ions such as tetraalkylammonium ions, pyridinium ions, imidazolium ions, etc., which can be used either singly or as a mixture of two or more of them.

Other examples than the above-mentioned which can be used as the electrolyte solution contained in the porous film constituting the electrolyte layer 7 include: combinations of an oxidized product and a reduced product of an organometallic complex having a transition metal such as cobalt, iron, copper, nickel, platinum, etc.; sulfur compounds such as combinations of sodium polysulfide or an alkyl thiol with an alkyl disulfide; viologen dyes; and a combination of hydroquinone with quinone.

Among the above-mentioned electrolytes, those electrolytes which are obtained by combining iodine (I₂) with lithium iodide (LiI), sodium iodide (NaI), or a quaternary ammonium compound such as imidazoium iodide are particularly preferable for use as the electrolyte in the electrolyte solution contained in the porous film constituting the electrolyte layer 7. The concentration of the electrolyte salt based on the amount of solvent is preferably 0.05 to 10 M, more preferably 0.2 to 3 M. The concentration of iodine (I₂) or bromine (Br₂) is preferably 0.0005 to 1 M, more preferably 0.001 to 0.5 M.

Besides, various additives such as 4-tert-butylpyridine, benzimidazoliums, etc. can be added to the electrolyte solution, for the purpose of enhancing open circuit voltage and short-circuit current.

Examples of the solvent which can be used as the solvent constituting the electrolyte solution, in general, include water, alcohols, ethers, esters, carbonic acid esters, lactones, carboxylic acid esters, phosphoric acid triesters, heterocyclic compounds, nitriles, ketones, amides, nitromethane, halogenated hydrocarbons, dimethyl sulfoxide, sulfolane, N-methylpyrrolidone, 1,3-dimethylimidazolidinone, 3-methyloxazolidinone, and hydrocarbons.

As the solvent constituting the electrolyte solution, an ionic liquid can also be used, whereby the problem of volatilization of the electrolyte solution can be improved. As the ionic liquid, those which have been known can be used, through appropriate selection according to the necessity. Specific examples of the ionic liquid are as follows.

EMImTCB: 1-ethyl-3-methylimidazolium tetracyanoborate

EMImTFSI: 1-ethyl-3-methylimidazolium bis(trifluoromethanesulfone)imide

EMImFAP: 1-ethyl-3-methylimidazolium tris(pentafluoroethyl)trifluorophosphate

EMImBF₄: 1-ethyl-3-methylimidazolium tetrafluoroborate

EMImOTf: 1-ethyl-3-methylimidazolium trifluoromethanesulfonate

P₂₂₂ MOMTFSI: triethyl(methoxymethyl)phosphonium bis(trifluoromethylsulfonyl)imide

The transparent substrate 1 is not specifically restricted insofar as it has a shape and a material such as to permit easy transmission of light therethrough. While various substrate materials can be used, it is particularly preferable to use a substrate material which has high transmittance with respect to visible light. In addition, a material which has high barrier performance for blocking water (moisture) and gases tending to enter into the dye-sensitized photoelectric conversion element from the outside and which is excellent in solvent resistance and weatherability is preferable for use here. Examples of the material which can be used for the transparent substrate 1 include transparent inorganic materials such as quartz, glass, etc., and transparent plastics such as polyethylene terephthalate, polyethylene naphthalate, polycarbonate, polystyrene, polyethylene, polypropylene, polyphenylene sulfide, polyvinylidene fluoride, acetyl cellulose, brominated phenoxy resin, aramids, polyimides, polystyrenes, polyarylates, polysulfones, polyolefins, etc. The thickness of the transparent substrate 1 is not particularly limited, and it can be appropriately selected taking into account light transmittance and performance as barrier between the inside and the outside of the photoelectric conversion element.

The transparent electrode 2 provided on the transparent substrate 1 is more preferable as its sheet resistance is lower. Specifically, the sheet resistance of the transparent electrode 2 is preferably not more than 500Ω/□, more preferably not more than 100Ω/□. As the material for forming the transparent electrode 2, known materials can be used, through appropriate selection according to the necessity. Specific examples of the material which can be used for forming the transparent electrode 2 include indium-tin composite oxide (ITO), fluorine-doped tin(IV) oxide SnO₂ (FTO), tin(IV) oxide SnO₂, zinc(II) oxide ZnO, and indium-zinc composite oxide (IZO). It is to be noted here, however, that these materials are not limitative of the material for forming the transparent electrode 2, and two or more of them can also be used in combination.

The photosensitizing dye to be bonded to the porous photoelectrode 3 is not specifically restricted insofar as it exhibits a photosensitizing action. While organometallic complexes, organic dyes, metal-semiconductor nanoparticles and the like can be used, those which have an acid functional group suitable for adsorption on the surface of the porous photoelectrode 3 are preferred. Among the photosensitizing dyes, those which have a carboxyl group or a phosphate group or the like are preferable, and those which have a carboxyl group are particularly preferable. Specific examples of the photosensitizing dye include: xanthene dyes such as Rhodamine B, Rose Bengale, eosine, erythrosine, etc.; cyanine dyes such as merocyanine, quinocyanine, cryptocyanine, etc.; basic dyes such as phenosafranine, Cabri blue, thiocine, Methylene Blue, etc.; and porphyrin compounds such as chlorophyll, zinc porphyrin, magnesium porphyrin, etc. Other examples include azo dyes, phthalocyanine compounds, cumarin compounds, pyridine complex compounds, anthraquinone dyes, polycyclic quinone dyes, traphenylmethane dyes, indoline dyes, perylene dyes, π-conjugate polymers such as polythiophene and dimers to 20-mers of their monomers, and quantum dots of CdS, CdSe, and the like. Among these dyes, those in which a ligand contains a pyridine ring or an imidazolium ring and which are each a complex of at least one metal selected from the group consisting of Ru, Os, Ir, Pt, Co, Fe and Cu, are preferred because they are high in quantum yield. Especially, dye molecules having cis-bis(isothiocyanato)-N,N-bis(2,2′-dipyridyl-4,4′-dicarboxylate)-ruthenium(II) or tris(isothiocyanato)-ruthenium(II)-2,2′:6′,2″-terpyridine-4,4′,4″-tricarboxylic acid as a fundamental skeleton thereof are preferred because of wide absorption wavelength range. It should be noted here, however, that the photosensitizing dye is not limited to the above-mentioned ones. While one of the above-mentioned photosensitizing dyes is typically used, a mixture of two or more of the photosensitizing dyes may also be used. In the case where a mixture of two or more photosensitizing dyes is used, the photosensitizing dyes preferably include an inorganic complex dye having a property for causing MLCT (Metal to Ligand Charge Transfer) and held on the porous photoelectrode 3, and an organic molecular dye having a property for intramolecular CT (Charge Transfer) and held on the porous photoelectrode 3. In this case, the inorganic complex dye and the organic molecule dye are adsorbed on the porous photoelectrode 3 in different conformations. The inorganic complex dye, preferably, has a carboxyl group or a phosphono group as the functional group for bonding to the porous photoelectrode 3. On the other hand, the organic molecular dye preferably has, on the same carbon atom, both a carboxyl group or a phosphono group and a cyano group, an amino group, a thiol group or a thione group as the functional groups for bonding to the porous photoelectrode 3. The inorganic complex dye is, for example, a polypyridine complex, whereas the organic molecular dye is, for example, an aromatic polycyclic conjugated molecule which has both an electron-donative group and an electron-acceptive group and has a property for intramolecular CT.

The method for adsorbing the photosensitizing dye onto the porous photoelectrode 3 is not specifically restricted. For example, the photosensitizing dye as above-mentioned may be dissolved in a solvent such as alcohols, nitriles, nitromethane, halogenated hydrocarbons, ethers, dimethyl sulfoxide, amides, N-methylpyrrolidone, 1,3-dimethylimidazolidinone, 3-methyloxazolidinone, esters, carbonic acid esters, ketones, hydrocarbons, water, etc., and then the porous photoelectrode 3 may be immersed in the solution containing the photosensitizing dye or the solution may be applied to the porous photoelectrode 3. Besides, for the purpose of suppressing association between molecules of the photosensitizing dye, deoxycholic acid or the like may be added to the solution containing the photosensitizing dye. Further, a UV absorber may be used together, if necessary.

After the photosensitizing dye is adsorbed on the porous photoelectrode 3, the surface of the porous photoelectrode 3 may be treated with an amine, for the purpose of accelerating the removal of the photosensitizing dye adsorbed in excess. Examples of the amine to be used here include 4-tert-butylpyridine and polyvinylpyridine, which may be used as it is or used in the state of being dissolved in an organic solvent.

As the material for the counter electrode 6, any conductive material can be used. In addition, an insulating material provided with a conductive layer on its side facing the electrolyte layer 7 can also be used. Preferably, a material which is electrochemically stable is used as the material for the counter electrode 6. Specific, desirable examples of such a material include platinum, gold, carbon, and conductive polymers.

Besides, for enhancing the catalytic action to the reduction reaction on the counter electrode 6, that surface of the counter electrode 6 which is in contact with the electrolyte layer 7 is preferably formed with a microstructure such as to increase the actual surface area. For instance, the surface of the counter electrode 6 is preferably formed to be in the state of platinum black in the case where the electrode material is platinum, and is preferably formed to be in the state of porous carbon in the case where the electrode material is carbon. Platinum black can be formed by subjecting platinum to an anodic oxidation treatment or a chloroplatinic acid treatment or the like, whereas the porous carbon can be formed by sintering of carbon particulates or calcination of an organic polymer or the like.

The counter electrode 6 is formed on the conductive layer 5 formed on one principal surface of the counter substrate 4, but this configuration is not limitative. As the material for the counter substrate 4, there can be used opaque glasses, plastics, ceramics, metals and the like, and there can also be used transparent materials, for example, transparent glasses and plastics. As the conductive layer 5, layers which are the same as or similar to those for the transparent electrode 2 can be used. Further, layers of opaque conductive materials can also be used.

As the material for the sealing material 8, there is preferably used a material which has light fastness, insulating properties, moisture barrier properties and the like. Specific examples of the material for the sealing material include epoxy resin, UV-curing resins, acrylic resin, polyisobutylene resin, EVA (ethylene vinyl acetate), ionomer resins, ceramics, and various fusible films.

### [Method of Manufacturing Dye-Sensitized Photoelectric Conversion Element]

Now, a method of manufacturing the above-mentioned dye-sensitized photoelectric conversion element will be described below.

First, a transparent conductive layer is formed on one principal surface of a transparent substrate 1 by sputtering or the like, to form a transparent electrode 2.

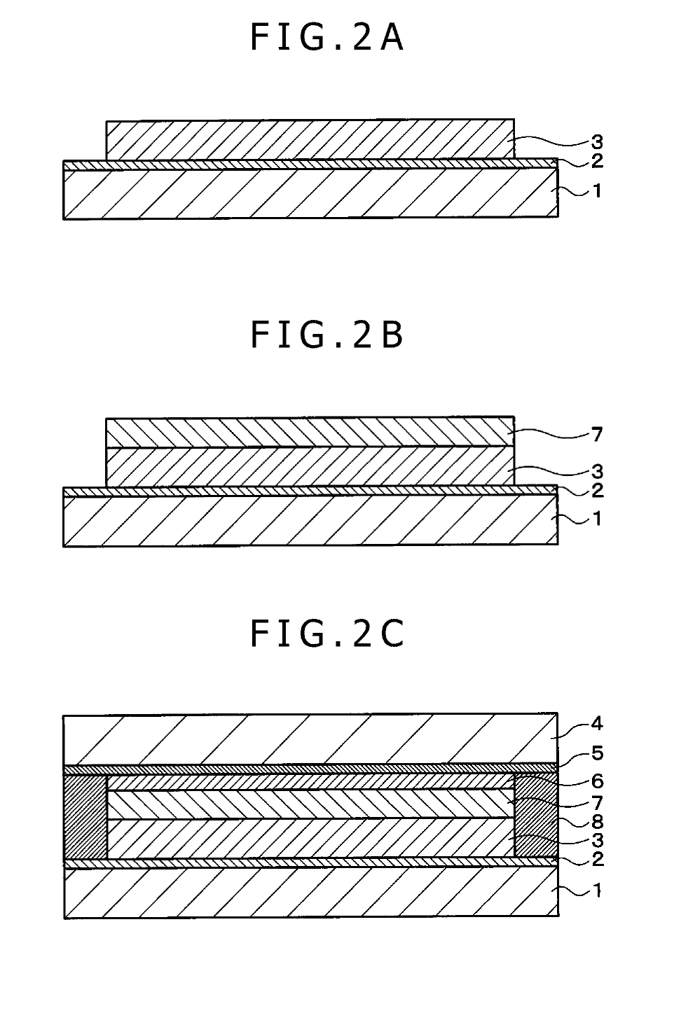

Next, as shown in FIG. 2A, a porous photoelectrode 3 is formed on the transparent electrode 2 on the transparent substrate 1. While the method of forming the porous photoelectrode 3 is not specifically restricted, a wet film forming method is preferably used, taking physical properties, convenience, production cost and the like into consideration. The wet film forming method is preferably carried out by uniformly dispersing a powder or sol of semiconductor particulates in a solvent such as water, to prepare a pasty dispersion, and applying or printing the dispersion onto the transparent electrode 2 on the transparent substrate 1. The dispersion applying method or printing method is not specifically restricted, and known methods can be used. Specific examples of the application method which can be used here include dipping method, spraying method, wire bar method, spin coating method, roller coating method, blade coating method, and gravure coating method. Besides, examples of the printing method which can be used here include relief printing method, offset printing method, gravure printing method, intaglio printing method, rubber plate printing method, and screen printing method.

In the case where anatase type TiO₂ is used as the material for the semiconductor particulates, the anatase type TiO₂ may be a commercial product which is in a powdery, sol or slurry state. Alternately, the anatase type TiO₂ may be prepared to have a predetermined particle diameter by a known method, such as hydrolysis of a titanium oxide alkoxide. In using a commercial powdery anatase type TiO₂, it is preferable to avoid agglomeration of the particles; therefore, it is preferable to pulverize the particles by use of mortar or a ball mill or the like at the time of preparing the pasty dispersion. In this instance, acetylacetone, hydrochloric acid, nitric acid, a surfactant, a chelating agent or the like can be added to the pasty dispersion, in order to prevent re-aggregation of the particles which have been prevented from agglomeration. Besides, a polymer such as polyethylene oxide, polyvinyl alcohol, etc. or a thickener such as a cellulose thickener can be added to the pasty dispersion, in order to increase the viscosity of the pasty dispersion.

After the semiconductor particulates are applied or printed onto the transparent electrode 2 in forming the porous photoelectrode 3, calcination is preferably conducted in order to electrically connect the semiconductor particulates to one another, to enhance the mechanical strength of the porous photoelectrode 3, and to enhance adhesion of the porous photoelectrode 3 to the transparent electrode 2. The range of calcination temperature is not particularly limited. If the calcination temperature is too high, however, the electric resistance of the transparent electrode 2 would be raised, and, further, the transparent electrode 2 might be melted. Normally, therefore, the calcination temperature is preferably 40 to 700° C., more preferably 40 to 650° C. In addition, calcination time also is not specifically restricted; normally, however, it is about 10 minutes to about 10 hours.

After the calcinations, a dipping treatment using, for example, an aqueous solution of titanium tetrachloride or a sol of titanium oxide particulates having a diameter of not more than 10 nm may be performed, for the purpose of increasing the surface areas of the semiconductor particulates or promoting necking among the semiconductor particulates. In the case where a plastic substrate is used as the transparent substrate 1 for supporting the transparent electrode 2, a process may be carried out in which the porous photoelectrode 3 is formed on the transparent electrode 2 by use of a pasty dispersion containing a binder and the porous photoelectrode 3 is pressure bonded to the transparent electrode 2 by a hot press.

Next, the transparent substrate 1 with the porous photoelectrode 3 formed thereon is immersed in a solution prepared by dissolving a photosensitizing dye in a predetermined solvent, thereby bonding the photosensitizing dye to the porous photoelectrode 3.

On the other hand, a conductive layer 5 is formed on the whole area of a surface of a counter electrode 4 by sputtering, for example, and thereafter a counter electrode 6 having a predetermined plan-view shape is formed on the conductive layer 5. The counter electrode 6 can be formed, for example, by a method in which a film to be a material of the counter electrode 6 is formed over the whole surface of the conductive layer 5 by, for example, sputtering or the like, and thereafter the film is patterned by etching.

Subsequently, as shown in FIG. 2B, an electrolyte layer 7 having a porous film containing an electrolyte solution is disposed on the porous photoelectrode 3 on the transparent substrate 1.

Next, as shown in FIG. 2C, the counter substrate 4 is disposed on the electrolyte layer 7, with the counter electrode 6 side down, and thereafter a sealing material 8 is formed at outer peripheral portions of the transparent substrate 1 and the counter substrate 4, thereby sealing the electrolyte layer 7. After the counter substrate 4 is disposed on the electrolyte layer 7, the counter electrode 4 may be pressed against the electrolyte layer 7 to compress the electrolyte layer 7 in a direction perpendicular to the plane thereof, as required. This ensures that when the thickness of the porous film constituting the electrolyte layer 7 is reduced by compression, the electrolyte solution contained in voids of the porous film is pressed out to permeate the porous photoelectrode 3, so that the electrolyte solution is easily distributed throughout the porous photoelectrode 3. The final thickness of the electrolyte layer 7 is, for example, 1 to 100 μm, preferably 1 to 50 μm.

By the steps as above-mentioned, the desired dye-sensitized photoelectric conversion element is manufactured.

### [Operation of Dye-Sensitized Photoelectric Conversion Element]

Now, operation of the dye-sensitized photoelectric conversion element will be described below.

The dye-sensitized photoelectric conversion element, upon incidence of light thereon, operates as a cell with the counter electrode 1 as a positive electrode and with the transparent electrode 2 as a negative electrode. The principle of this operation is as follows. Incidentally, here, it is assumed that FTO is used as the material for the transparent electrode 2, while TiO₂ is used as the material for the porous photoelectrode 3 and oxidation-reduction species of I⁻/I₃⁻ are used as a redox pair, but this assumption is not limitative. Besides, it is assumed that one kind of photosensitizing dye is bonded to the porous photoelectrode 3.

When photons transmitted through the transparent substrate 1 and the transparent electrode 2 and entering the porous photoelectrode 3 are absorbed by the photosensitizing dye bonded to the porous photoelectrode 3, electrons in the photosensitizing dye are excited from a ground state (HOMO) to an excited state (LUMO). The thus excited electrons are drawn out into a conduction band of TiO₂ constituting the porous photoelectrode 3, through the electrical coupling between the photosensitizing dye and the porous photoelectrode 3, and pass through the porous photoelectrode 3, to reach the transparent electrode 2.

On the other hand, the photosensitizing dye having lost the electrons accepts electrons from a reducing agent, for example, I⁻ in the electrolyte layer 7 by the following reaction, to produce an oxidizing agent, for example, I₃⁻ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 by a reaction reverse to the above-mentioned, and is thereby reduced to the original reducing agent.

I₃⁻→I₂+I⁻

I₂+2e⁻→2I⁻

The electrons sent from the transparent electrode 2 to an external circuit perform an electrical work in the external circuit, and thereafter return to the counter electrode 6. In this manner, optical energy is converted into electrical energy, without leaving any change in the photosensitizing dye or in the electrolyte layer 7.

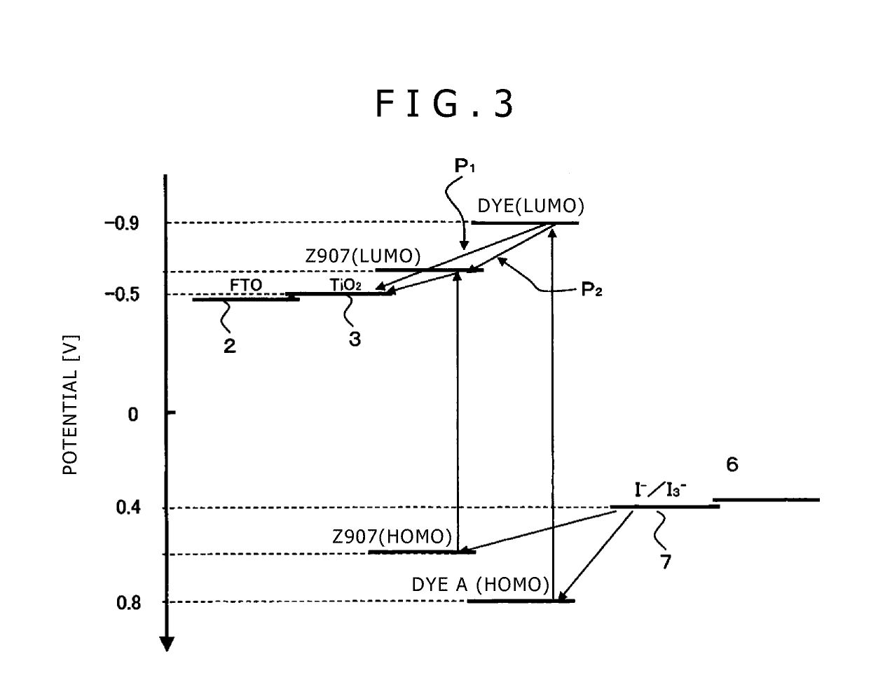

Now, operation of a dye-sensitized photoelectric conversion element in which two kinds of photosensitizing dyes are bonded to the porous photoelectrode 3 will be described below. Here, it is assumed that Z907 and Dye A are bonded to the porous photoelectrode 3, the assumption being a non-limitative example. Dye A is 2-Cyano-3-[4-[4-(2,2-diphenylethenyl)phenyl]-1,2,3,3a,4,8b-hexahydrocyclopent[b]indol-7-yl]-2-propenoic acid. FIG. 3 is an energy chart for illustrating the operation principle of this dye-sensitized photoelectric conversion element. The dye-sensitized photoelectric conversion element, upon incidence of light thereon, operates as a cell with the counter electrode 6 as a positive electrode and with the transparent electrode 2 as a negative electrode. The principle of the operation is as follows. Incidentally, here, it is assumed that FTO is used as the material for the transparent electrode 2, while TiO₂ is used as the material for the porous photoelectrode 3 and oxidation-reduction species of I⁻/I₃⁻ are used as a redox pair, but this assumption is not limitative.

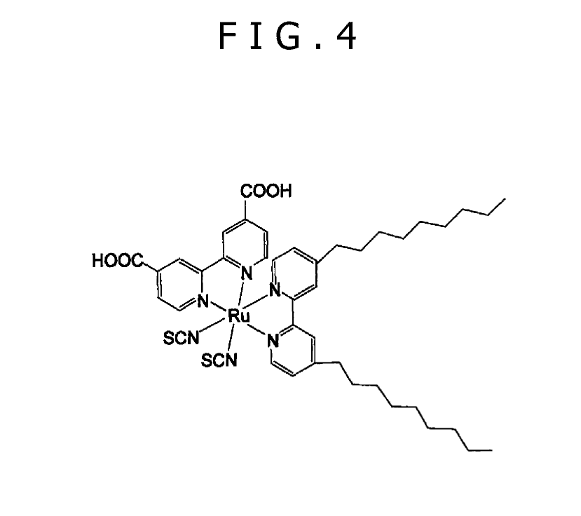

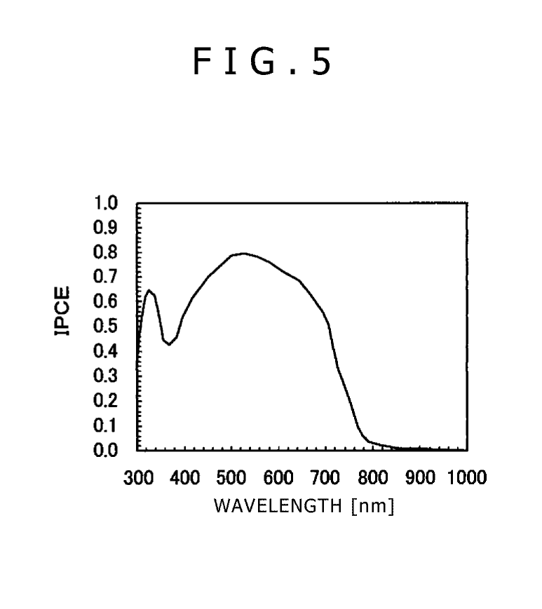

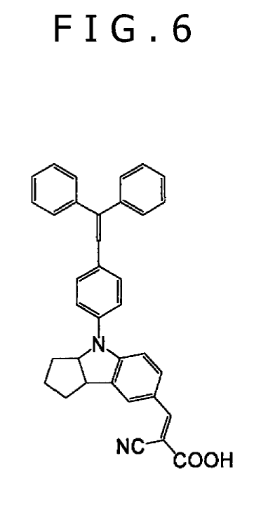

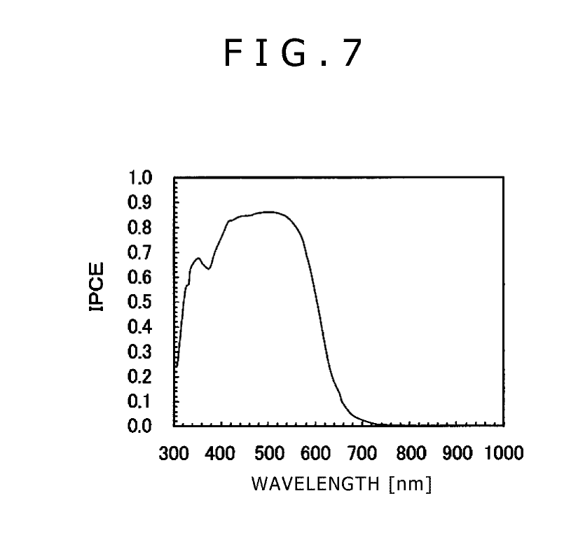

FIG. 4 shows the structural formula of Z907, and FIG. 5 shows the measurement results of IPCE (Incident Photon-to-current Conversion Efficiency) spectrum when Z907 alone is adsorbed on the surface of the porous photoelectrode 3. In addition, FIG. 6 shows the structural formula of Dye A, and FIG. 7 shows the measurement results of IPCE spectrum when Dye A alone is adsorbed on the surface of the porous photoelectrode 3. As shown in FIGS. 5 and 7, Z907 can absorb light in a wide wavelength range, but shows an insufficient-absorbance region in a short wavelength region; in the short wavelength region, Dye A having a high absorbance in this short wavelength region assists absorption of light. In other words, Dye A functions as a photosensitizing dye having a high absorbance in the short wavelength region.

As shown in FIG. 4, Z907 has carboxyl groups (—COOH) as functional groups for strong bonding to the porous photoelectrode 3, and the carboxyl group(s) is bonded to the porous photoelectrode 3. On the other hand, as shown in FIG. 6, Dye A has a structure in which a carboxyl group (—COOH) as a functional group for strong bonding to the porous photoelectrode 3 and a cyano group (—CN) as a functional group for weak bonding to the porous photoelectrode 3 are bonded to the same carbon atom. In addition, in Dye A, the carboxyl group and the cyano group bonded to the same carbon atom are both bonded to the porous photoelectrode 3. In other words, Dye A is adsorbed on the porous photoelectrode 3 through the carboxyl group and the cyano group bonded to the same carbon atom, naturally in a conformation different from the conformation of Z907 which is adsorbed on the porous photoelectrode 3 through only the carboxyl group(s). Here, if the plurality of functional groups bonded to the same carbon atom in Dye A are all functional groups for strong bonding to the porous photoelectrode 3, the degree of freedom with respect to the conformation of Dye A adsorbed on the porous photoelectrode 3 is low, so that the effect of the presence of the plurality of functional groups bonded to the same carbon atom would be exhibited with difficulty. On the contrary, in Dye A, the cyano group for weak bonding to the porous photoelectrode 3 functions in an assisting or auxiliary manner, and does not hamper the bonding to the porous photoelectrode 3 of the carboxyl group for strong bonding. As a result, in Dye A, the effect of the bonding of both the carboxyl group and the cyano group to the same carbon atom is exhibited effectively. In other words, even when Dye A and Z907 are located adjacent to each other on the surface of the porous photoelectrode 3, they can coexist without any strong interaction therebetween, so that they do not spoil each other's photoelectric conversion performance. On the other hand, Dye A is effectively interposed between molecules of Z907 bonded to the same porous photoelectrode 3 as that to which it is bonded, thereby to suppress association of the molecules of Z907 and to prevent needless transfer of electrons among the molecules of Z907. Therefore, from Z907 having absorbed light, excited electrons are efficiently extracted to the porous photoelectrode 3, without any needless transfer among the molecules of Z907, so that the photoelectric conversion efficiency relating to Z907 is enhanced. Besides, excited electrons in Dye A having absorbed light are extracted to the porous photoelectrode 3 through the carboxyl group, so that transfer of electric charge to the porous photoelectrode 3 is performed efficiently.

When photons transmitted through the transparent substrate 1, the transparent electrode 2 and the porous photoelectrode 3 are absorbed by the photosensitizing dyes bonded to the porous photoelectrode 3, namely, Z907 and Dye A, electrons in Z907 and Dye A are excited from the ground state (HOMO) to the excited state (LUMO). In this instance, since the photosensitizing dyes include Z907 and Dye A, light in a wider wavelength region can be absorbed at a higher light absorptivity, as compared with the case of a dye-sensitized photoelectric conversion element wherein the photosensitizing dye consists of a single dye.

The electrons in the excited state are drawn out into the conduction band of the porous photoelectrode 3 through the electrical coupling between the photosensitizing dyes (namely, Z907 and Dye A) and the porous photoelectrode 3, and pass through the porous photoelectrode 3, to each the transparent electrode 2. In this instance, minimum excitation energies, or HOMO-LUMO gaps, of Z907 and Dye A are different from each other, and Z907 and Dye A are bonded to the porous photoelectrode 3 in different conformations; therefore, needless electron transfer is not liable to occur between Z907 and Dye A. Accordingly, Z907 and Dye A would not lower each other's quantum yield, the photoelectric conversion performances of Z907 and Dye A are exhibited favorably, and the quantity of current generated is greatly enhanced. Besides, in this system, there are two kinds of paths through which the electrons in the excited state in Dye A are drawn out into the conduction band of the porous photoelectrode 3. One is a direct path P₁ through which the electrons are drawn out directly from the excited state of Dye A into the conduction band of the porous photoelectrode 3. The other is an indirect path P₂ through which the electrons in the excited state of Dye A are drawn out first into the excited state of Z907 present at a lower energy level, and, thereafter, the electrons are drawn out from the excited state of Z907 into the conduction band of the porous photoelectrode 3. Due to the contribution of the indirect path P₂, photoelectric conversion efficiency of Dye A is enhanced in the system in which Z907 exists in addition to Dye A.

On the other hand, Z907 and Dye A having lost the electrons accept electrons from a reducing agent, for example, I⁻ present in the electrolyte layer 7 through the following reaction, and produce an oxidizing agent, for example, I₃ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above-mentioned, and is thereby reduced to the original reducing agent.

I₃⁻→I₂+I⁻

I₂+2e⁻→2I⁻

The electrons sent out from the transparent electrode 2 to an external circuit perform an electrical work in the external circuit, and thereafter return to the counter electrode 6. In this way, optical energy is converted into electrical energy, without leaving any change in any of the photosensitizing dyes, namely, Z907 and Dye A, and the electrolyte layer 7.

### Example 1

A dye-sensitized photoelectric conversion element was manufactured in the following manner.

A pasty dispersion of TiO₂ as raw material in forming a porous photoelectrode 3 was prepared with reference to “Shikiso Zokan Taiyo Denchi No Saishin Gijutsu (The Latest Technologies of Dye-Sensitized Solar Cells)” (supervised by Hironori Arakawa, 2001, CMC Publishing Co., Ltd.). Specifically, first, 125 ml of titanium isopropoxide was slowly added dropwise to 750 ml of a 0.1 M aqueous solution of nitric acid with stirring at room temperature. After the dropwise addition, the admixture was transferred into a 80° C. thermostat, and stirring was continued for eight hours, to obtain a milky white semi-transparent sol solution. The sol solution was let cool to room temperature, was filtered through a glass filter, and thereafter a solvent was added thereto until the volume of the solution became 700 ml. The sol solution thus obtained was transferred into an autoclave, a hydrothermal reaction was let proceed at 220° C. for 12 hours, and then an ultrasonic treatment as a dispersing treatment was continued for one hour. Next, the solution was concentrated at 40° C. by use of an evaporator, to adjust the TiO₂ content to 20 wt %. The thus concentrated sol solution was admixed with polyethylene glycol (molecular weight: 500,000) in an amount corresponding to 20% of the mass of TiO₂ and anatase-type TiO₂ with a particle diameter of 200 nm in an amount corresponding to 30% of the mass of TiO₂, and the resulting admixture was uniformly blended by a stirrer-deaerator, to obtain a pasty dispersion of TiO₂ having an increased viscosity.

The above-mentioned pasty dispersion of TiO₂ was applied onto an FTO layer, serving as a transparent electrode 2, by blade coating method, to form a particulate layer measuring 5 mm×5 mm and 200 μm in thickness. Thereafter, the assembly was held at 500° C. for 30 min, to sinter the TiO₂ particulates on the FTO layer. A 0.1 M aqueous solution of titanium(IV) chloride TiCl₄ was dropped onto the sintered TiO₂ film, then the assembly was held at room temperature for 15 hours, was washed, and was subjected again to calcinations at 500° C. for 30 minutes. Thereafter, the sintered TiO₂ body was irradiated with UV light for 30 minutes by use of a UV irradiation apparatus, whereby a treatment for removing impurities such as organic matter contained in the sintered TiO₂ body through oxidative decomposition by the photocatalytic action of TiO₂ was conducted and a treatment for enhancing an activity of the sintered TiO₂ was performed, to obtain a porous photoelectrode 3.

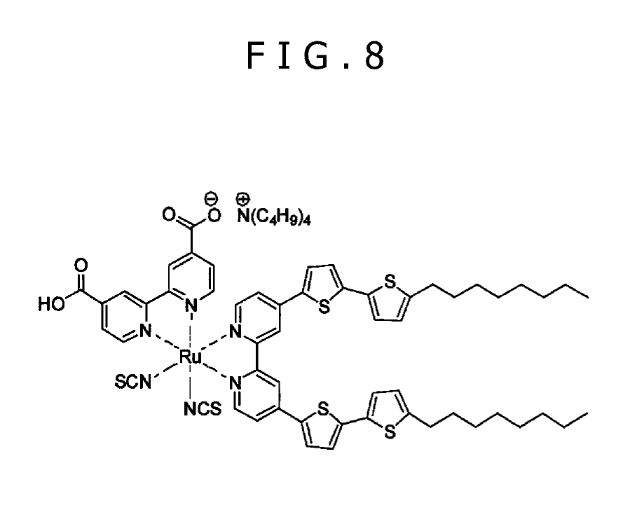

In 50 ml of a mixed solvent prepared by mixing acetonitrile and tert-butanol in a volume ratio of 1:1, 23.8 mg of sufficiently purified Z991 as photosensitizing dye was dissolved, to prepare a photosensitizing dye solution. FIG. 8 shows the structural formula of Z991. As shown in FIG. 8, Z991 has a carboxyl group (—COOH) as a functional group for strong bonding to the porous photoelectrode 3, and the carboxyl group is bonded to the porous photoelectrode 3.

Incidentally, in the case where Z907 and Dye A are used as photosensitizing dyes, 23.8 mg of sufficiently puriried Z907 and 2.5 mg of Dye A are dissolved in 50 ml of a mixed solvent prepared by mixing acetonitrile and tert-butanol in a volume ratio of 1:1, to prepare a photosensitizing dye solution.

Next, in the photosensitizing dye solution prepared as above, the porous photoelectrode 3 was immersed at room temperature for 24 hours, to hold the photosensitizing dye(s) on the surfaces of TiO₂ particulates. Subsequently, the porous photoelectrode 3 was cleaned sequentially with an acetonitrile solution of 4-tert-butylpyridine and with acetonitrile, thereafter the solvents were evaporated off in a dark plate, and the porous photoelectrode 3 was dried.

On the other hand, 1.0 M of 1-propyl-3-methylimidazolium iodide (MPImI), 0.1 M of iodine I₂, and 0.3 M of N-butylbenzimidazole (NBB) as an additive were dissolved in 3-methoxypropionitrile (MPN) used as solvent, to prepare an electrolyte solution. Then, a porous film of polyolefin having a porosity of 71.4% and a thickness of 31.2 μm was impregnated with the electrolyte solution.

Incidentally, in the case where Z907 and Dye A are used as photosensitizing dyes, for example, 0.030 g of sodium iodide (NaI), 1.0 g of 1-propyl-2,3-dimethylimidazolium iodide, 0.10 g of iodine I₂, and 0.054 g of 2-NH2-Py as an additive are dissolved in 2.0 g of 3-methoxypropionitrile (MPN), to prepare an electrolyte solution.

Subsequently, the porous polyolefin film preliminarily impregnated with the electrolyte solution as above-mentioned was disposed on the porous photoelectrode 3 on the transparent substrate 1, to form an electrolyte layer 7.

Next, the porous film was compressed in a direction perpendicular to the film plane by a press. After the compression, the actual porosity of the porous film was 50%.

Subsequently, an ionomer resin film and an acrylic UV-curing resin were provided as a sealing material at the outer periphery of the electrolyte layer 7.

A counter electrode 6 was formed in the following manner. On an FTO layer preliminarily formed with a liquid pouring port having a diameter of 0.5 mm, a 50 nm-thick chromium layer and a 100 nm-thick platinum layer were sequentially stacked by a sputtering method. Then, the platinum layer was spray-coated with an isopropyl alcohol (2-propanol) solution of chloroplatinic acid, followed by heating at 385° C. for 15 minutes, to obtain the counter electrode 6.

The thus formed counter electrode 6 was disposed on the above-mentioned electrolyte layer 7, and was adhered to the sealing material disposed at the outer periphery of the electrolyte layer 7, to complete the dye-sensitized photoelectric conversion element.

### Example 2

A dye-sensitized photoelectric conversion element was manufactured in the same manner as in Example 1, except that a porous polyolefin film having a porosity of 70.7% and a thickness of 30 μm was used as a porous film to be impregnated with an electrolyte solution, thereby forming an electrolyte layer 7.

### Example 3

A dye-sensitized photoelectric conversion element was manufactured in the same manner as in Example 1, except that a porous polyolefin film having a porosity of 70.5% and a thickness of 44 μm was used as a porous film to be impregnated with an electrolyte solution, thereby forming an electrolyte layer 7.

### Example 4

A dye-sensitized photoelectric conversion element was manufactured in the same manner as in Example 1, except that a porous polyester film having a porosity of 79% and a thickness of 28 μm was used as a porous film to be impregnated with an electrolyte solution, thereby forming an electrolyte layer 7.

### Example 5

A dye-sensitized photoelectric conversion element was manufactured in the same manner as in Example 1, except that a porous cellulose film having a porosity of 72.8% and a thickness of 29.8 μm was used as a porous film to be impregnated with an electrolyte solution, thereby forming an electrolyte layer 7.

### Example 6

A dye-sensitized photoelectric conversion element was manufactured in the same manner as in Example 1, except that a porous polyester film having a porosity of 78.3% and a thickness of 32 μm was used as a porous film to be impregnated with an electrolyte solution, thereby forming an electrolyte layer 7.

### Example 7

A dye-sensitized photoelectric conversion element was manufactured in the same manner as in Example 1, except that a porous polyester film having a porosity of 82.7% and a thickness of 22 μm was used as a porous film to be impregnated with an electrolyte solution, thereby forming an electrolyte layer 7.

### Comparative Example 1

A dye-sensitized photoelectric conversion element was manufactured in the same manner as in Example 1, except that an electrolyte layer 7 composed only of an electrolyte solution was formed without using any porous film.

Table 1 below shows collectively the material, porosity, film thickness and actual porosity of the porous film used in forming the electrolyte layer 7 in each of the dye-sensitized photoelectric conversion elements manufactured in Examples 1 to 7. Here, the actual porosity of the porous film is represented as follows.

Actual porosity (%)=100−{100−[porosity (%) of film]}×[volume (m³) of film]/{[volume (m³) of electrolyte layer 7]−[bulk volume (m³) of porous photoelectrode 3]}

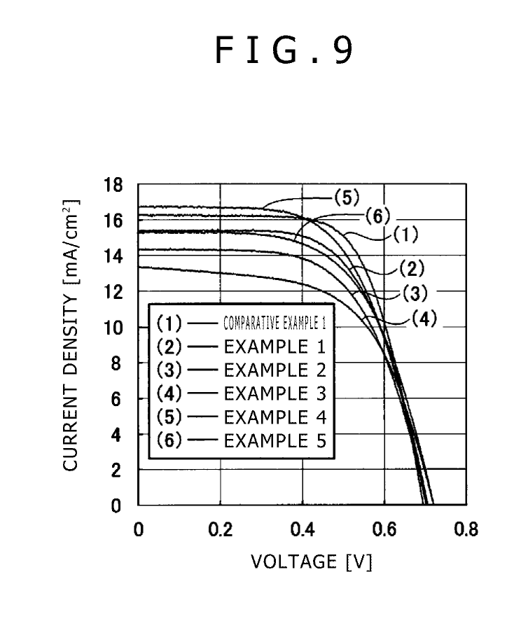

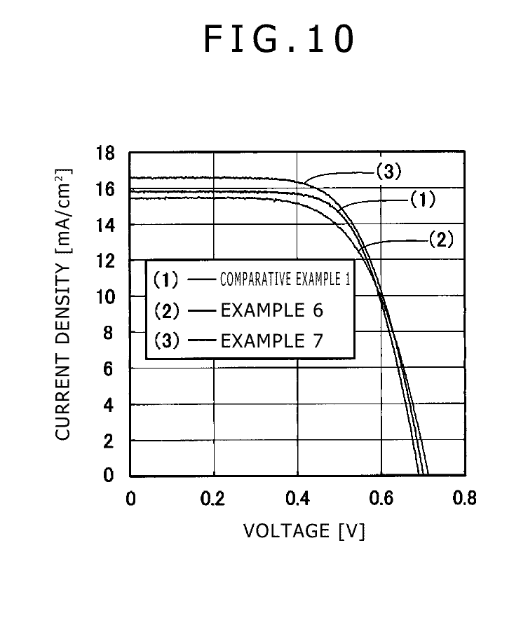

For the dye-sensitized photoelectric conversion elements manufactured in Examples 1 to 7 and Comparative Example 1, current-voltage characteristic was measured. The measurement was made by irradiating each dye-sensitized photoelectric conversion element with pseudo-sunlight (artificial, or simulated, solar radiation) (AM 1.5, 100 mW/cm²). FIGS. 9 and 10 show the measurement results of current-voltage characteristic, for these dye-sensitized photoelectric conversion elements. In addition, Tables 2 and 3 below show open circuit voltage V_{oc}, current density J_{sc}, fill factor (FF), photoelectric conversion efficiency (Eff) and internal resistance (Rₛ), for these dye-sensitized photoelectric conversion elements.

TABLE 2

| Sample | V_{oc}(V) | J_{sc}(mA/cm²) | FF(%) | Eff(%) | Rₛ(Ω) |
|---|---|---|---|---|---|
| Comparative | 0.695 | 16.27 | 67.1 | 7.58 | 38.71 |
| Example 1 | | | | | |
| Example 1 | 0.706 | 15.41 | 62.6 | 6.80 | 45.88 |
| Example 2 | 0.704 | 14.33 | 61.1 | 6.17 | 51.59 |
| Example 3 | 0.720 | 13.35 | 59.3 | 5.70 | 58.80 |
| Example 4 | 0.701 | 16.74 | 60.8 | 7.13 | 45.44 |
| Example 5 | 0.720 | 15.30 | 60.0 | 6.61 | 53.07 |

TABLE 3

| Sample | V_{oc}(V) | J_{sc}(mA/cm²) | FF(%) | Eff(%) | Rₛ(Ω) |
|---|---|---|---|---|---|
| Comparative | 0.690 | 15.83 | 67.1 | 7.34 | 39.46 |
| Example 1 | | | | | |
| Example 6 | 0.713 | 15.46 | 62.8 | 6.93 | 47.34 |
| Example 7 | 0.701 | 16.60 | 64.7 | 7.53 | 40.66 |

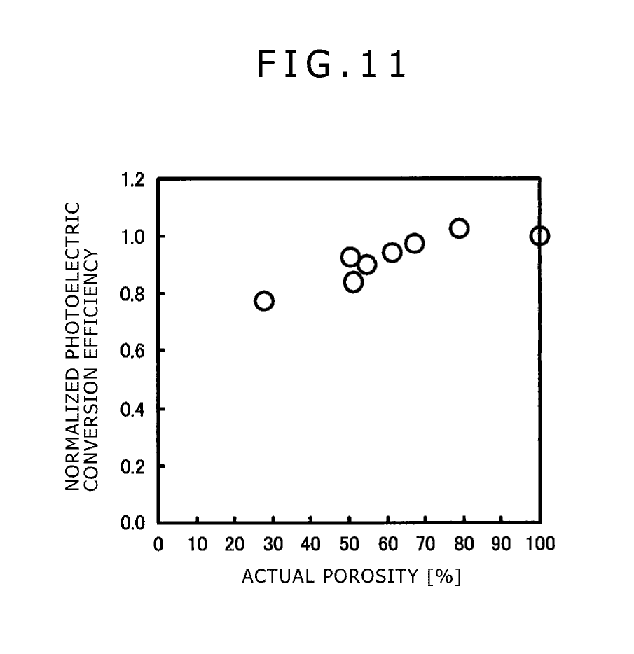

FIG. 11 shows the relationship between the actual porosity of the porous film used in forming the electrolyte layer 7, in each of the dye-sensitized photoelectric conversion elements manufactured in Examples 1 to 7, and the normalized photoelectric conversion efficiency, obtained by normalizing the photoelectric conversion efficiency of each of the dye-sensitized photoelectric conversion elements of Examples 1 to 7 by the photoelectric conversion efficiency of the dye-sensitized photoelectric conversion element of Comparative Example 1.

From Tables 2 and 3 and FIGS. 9 to 11, it is seen that the photoelectric conversion efficiencies of the dye-sensitized photoelectric conversion elements of Examples 1 to 7 are, in general, slightly lower than the photoelectric conversion element of the dye-sensitized photoelectric conversion element of Comparative Example 1. However, the photoelectric conversion efficiencies of the dye-sensitized photoelectric conversion elements of Examples 1, 2, and 4 to 7, in which a porous film with an actual porosity of not less than 50% was used for forming the electrolyte layer 7, are not less than 80% of the photoelectric conversion efficiency of the dye-sensitized photoelectric conversion element of Comparative Example 1. In addition, the photoelectric conversion efficiencies of the dye-sensitized photoelectric conversion elements of Examples 1, 2, and 4 to 7 show a tendency of increase as the actual porosity of the porous film used in forming the electrolyte layer 7 increases; eventually, the photoelectric conversion efficiencies become comparable to the photoelectric conversion efficiency of the dye-sensitized photoelectric conversion element of Comparative Example 1, when the actual porosity is not less than 80% and less than 100%.

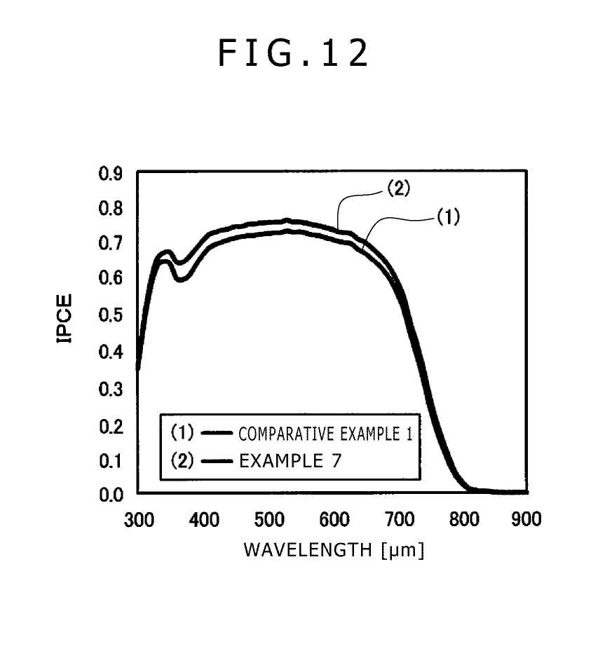

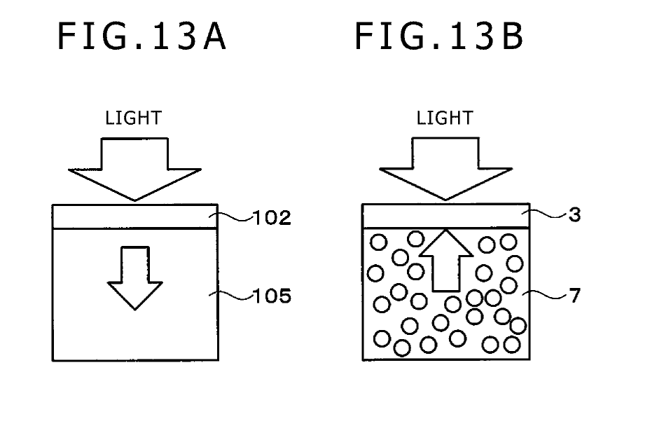

FIG. 12 shows the measurement results of IPCE spectrum, for the dye-sensitized photoelectric conversion element of Example 7 in which a porous film having an actual porosity of 79% was used in forming the electrolyte layer 7 and for the dye-sensitized photoelectric conversion element of Comparative Example 1 in which the electrolyte layer 7 was formed only from the electrolyte solution. From FIG. 12, it is seen that the photoelectric conversion element of Example 7 has an increased photoelectric conversion efficiency in the whole wavelength region, as compared with the dye-sensitized photoelectric conversion element of Comparative Example 1. The reason for this is considered as follows. As shown in FIG. 13A, in the dye-sensitized photoelectric conversion element of Comparative Example 1, that portion of the light incident on the porous photoelectrode 102 which fails to be absorbed by the photosensitizing dye is transmitted through the electrolyte layer 105 composed only of the electrolyte solution. On the other hand, in the dye-sensitized photoelectric conversion element of Example 7, that portion of the light incident on the porous photoelectrode 3 which fails to be absorbed by the photosensitizing dye and is therefore incident on the electrolyte layer 7 is, because the porous film constituting the electrolyte layer 7 has many voids, effectively scattered by the porous film. The light thus scattered by the electrolyte layer 7 is again incident on the porous photoelectrode 3 from the back side, to be absorbed by the photosensitizing dye. In this case, the light scattered by the porous film contains much component that is obliquely incident on the surface of the porous photoelectrode 3; therefore, the optical path length inside the porous photoelectrode 3 is greatly elongated, leading to an increase in the coefficient of trapping of the incident light by the porous photoelectrode 3. As a result, in the dye-sensitized photoelectric conversion element of Example 7, the photoelectric conversion efficiency is increased in the whole wavelength region, as compared with the dye-sensitized photoelectric conversion element of Comparative Example 1.

As above-mentioned, according to the first embodiment of the present disclosure, the electrolyte layer 7 of the dye-sensitized photoelectric conversion element has the porous film containing the electrolyte solution. Therefore, the electrolyte layer 7 is in solid state, which ensures that when the photoelectric conversion element is broken or damaged, leakage of the electrolyte solution can be effectively prevented. In addition, the porous photoelectrode 3 and the counter electrode 6 are separated from each other by the insulating porous film, which ensures that even if the dye-sensitized photoelectric conversion element is bent, it is possible to prevent electrical insulation performance between the porous photoelectrode 3 and the counter electrode 6 from being lowered. Besides, unlike in the case of the dye-sensitized photoelectric conversion element according to the related art, it becomes unnecessary to provide a liquid pouring hole for pouring the electrolyte solution therethrough, to wipe away the electrolyte solution after pouring the electrolyte solution, or to close the liquid pouring hole. Therefore, the dye-sensitized photoelectric conversion element can be manufactured easily and simply. Moreover, since the electrolyte solution can actually be treated as a film, a treatment of the electrolyte solution can be extremely simplified. Therefore, for example in the case of manufacturing a dye-sensitized photoelectric conversion element on a transparent film by a roll-to-roll process, the electrolyte layer 7 having the porous film containing the electrolyte solution can be adhered as a film to the transparent film. Further, in this dye-sensitized photoelectric conversion element, that portion of the incident light which fails to be absorbed by the photosensitizing dye adsorbed on the porous photoelectrode 3 is scattered by the electrolyte layer 7, to be again incident on the porous photoelectrode 3. As a result, in this dye-sensitized photoelectric conversion element, it is possible to obtain a high photoelectric conversion efficiency comparable to that of the dye-sensitized photoelectric conversion element according to the related art in which the electrolyte layer 7 is composed only of the electrolyte solution. Then, by use of this excellent dye-sensitized photoelectric conversion element, a high-performance electronic apparatus and the like can be realized.

### 2. Second Embodiment

### Dye-Sensitized Photoelectric Conversion Element

A dye-sensitized photoelectric conversion element according to a second embodiment of the present disclosure has a configuration similar to that of the dye-sensitized photoelectric conversion element according to the first embodiment above.

### [Method of Manufacturing Dye-Sensitized Photoelectric Conversion Element]

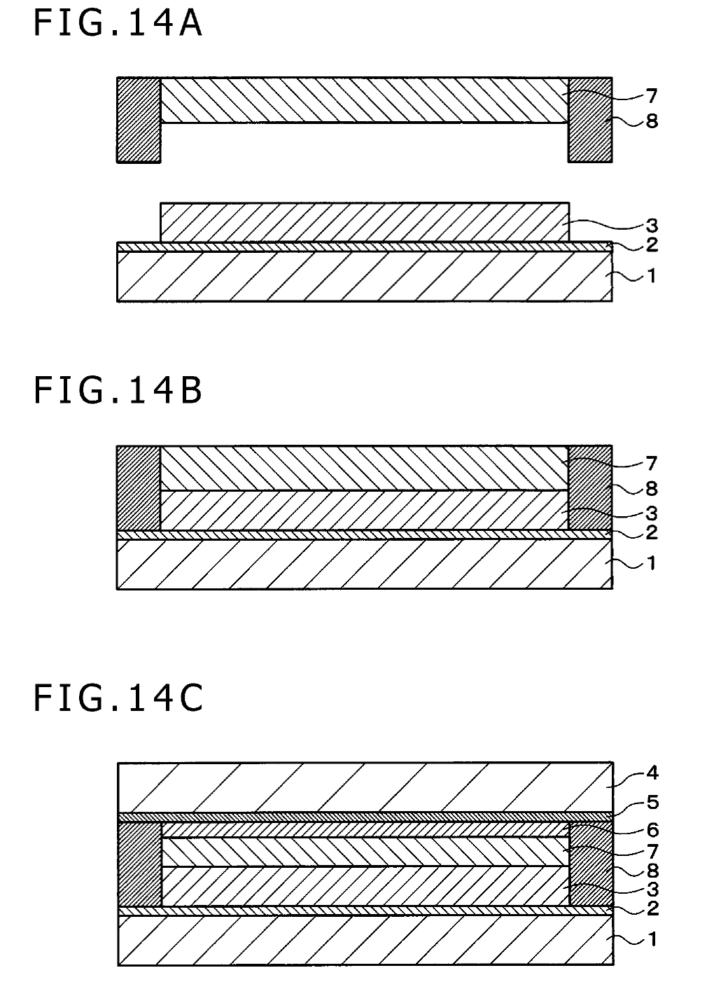

FIGS. 14A to 14C illustrate a method of manufacturing the dye-sensitized photoelectric conversion element according to the second embodiment.

As shown in FIG. 14A, in the method of manufacturing the dye-sensitized photoelectric conversion element, first, a porous photoelectrode 3 is formed in the same manner as in the first embodiment.

On the other hand, as shown in FIG. 14A, for example, an integral-type film in which a thermosetting sealing material 8 is formed at the outer periphery of and integrally with an electrolyte layer 7 having a porous film containing an electrolyte solution is prepared. The thickness of the electrolyte layer 7 in this state is greater than the thickness of the electrolyte layer 7 in a final state. The thickness of the sealing material 8 is greater than the thickness of the electrolyte layer 7, and is so set that sufficient sealing can be performed by the sealing material 8 finally.

Next, as shown in FIG. 14B, the integral-type film in which the sealing material 8 was formed at the outer periphery of the electrolyte layer 7 having the porous film containing the electrolyte solution is disposed on the porous photoelectrode 3.

Subsequently, as shown in FIG. 14C, a counter electrode 6 provided on a counter substrate 4 is disposed on the electrolyte layer 7 and the sealing material 8, the counter substrate 4 is pressed against the electrolyte layer 7 to compress the electrolyte layer 7 in the direction perpendicular to the plane thereof, and the sealing material 8 is cured (hardened) by heating, to complete sealing. In this instance, the thickness of the porous film constituting the electrolyte layer 7 is reduced by the compression; in view of this, such a setting is made that the final actual porosity of the porous film will be a desired value.

In this manner, the desired dye-sensitized photoelectric conversion element is manufactured.

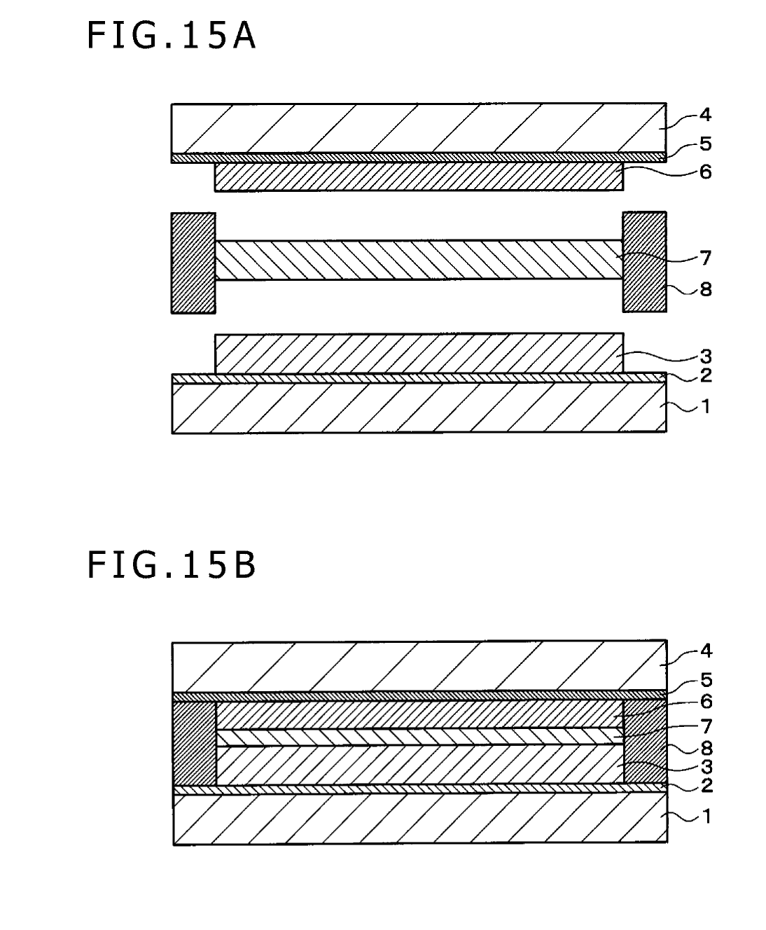

On the other hand, in the case where a bulky (or thick) counter electrode 6 having porous carbon or porous metal is used in the dye-sensitized photoelectric conversion element, the integral-type film of the electrolyte layer 7 and the sealing material 8 is formed taking into account the bulk of the counter electrode 6 in addition to the bulk of the porous photoelectrode 3. FIGS. 15A and 15B illustrate a method of manufacturing such a dye-sensitized photoelectric conversion element as just-mentioned.

As shown in FIG. 15A, in the method of manufacturing this dye-sensitized photoelectric conversion element, first, a porous film 3 is formed in the same manner as in the first embodiment.

On the other hand, as shown in FIG. 15A, an integral-type film in which a thermosetting sealing material 8 is formed at the outer periphery of and integrally with an electrolyte layer 7 having a porous film containing an electrolyte solution is prepared. The thickness of the electrolyte layer 7 in this state is greater than the thickness of the electrolyte layer 7 in a final state. The thickness of the sealing material 8 is greater than the thickness of the electrolyte layer 7, and is so set that sufficient sealing can be performed by the sealing material 8 finally. In addition, an assembly in which a counter electrode 6 is provided over a counter substrate 4, with a conductive layer 5 therebetween, is prepared.

Next, as shown in FIG. 15B, the integral-type film in which the sealing material 8 was formed at the outer periphery of the electrolyte layer 7 having the porous film containing the electrolyte solution is disposed on the porous photoelectrode 3. Subsequently, the counter electrode 6 provided on the counter substrate 4 is disposed on the electrolyte layer 7 and the sealing material 8, and the counter substrate 4 is pressed against the electrolyte layer 7. In this way, the electrolyte layer 7 is compressed in the direction perpendicular to the plane thereof, and the sealing material 8 is cured (hardened) by heating, to complete sealing. In this instance, the thickness of the porous film constituting the electrolyte layer 7 is reduced by the compression; in view of this, such a setting is made that the final actual porosity of the porous film will be a desired value.

In this way, the desired dye-sensitized photoelectric conversion element is manufactured.

In other points than the above-mentioned, the present embodiment is the same as the first embodiment.

According to this second embodiment, a merit that the process of forming the sealing material 8 can be omitted and the dye-sensitized photoelectric conversion element can therefore be manufactured more easily can be obtained, in addition to the same merits as in the first embodiments.

### 3. Third Embodiment

### Dye-Sensitized Photoelectric Conversion Element

A dye-sensitized photoelectric conversion element according to a third embodiment of the present disclosure differs from the dye-sensitized photoelectric conversion element according to the first embodiment above in that an additive having a pKₐ in the range of 6.04≦pKₐ≦7.3 is added to an electrolyte solution contained in a porous film constituting an electrolyte layer 7. Examples of such an additive include pyridine additives, additives having a heterocyclic ring, etc. Specific examples of the pyridine additives include 2-NH2-Py, 4-MeO-Py, and 4-Et-Py. Specific examples of the additives having a heterocyclic ring include MIm, 24-Lu, 25-Lu, 26-Lu, 34-Lu, and 35-Lu.

Besides, as solvent of the electrolyte solution contained in the electrolyte layer 7, there is used a solvent having a molecular weight of not less than 47.36. Examples of such a solvent include 3-methoxypropionitrile (MPN), methoxyacetonitrile (MAN), and a mixed liquid of acetonitrile (AN) and valeronitrile (VN).

### [Method of Manufacturing Dye-Sensitized Photoelectric Conversion Element]

A method of manufacturing this dye-sensitized photoelectric conversion element is the same as the method of manufacturing the dye-sensitized photoelectric conversion element according to the first embodiment above, except that the additive having a pKₐ in the range of 6.04≦pKₐ≦7.3 is added to the electrolyte solution contained in the porous film constituting the electrolyte layer 7.

### Example 8

In the same electrolyte solution as used in Example 1, 0.054 g of 2-NH2-Py was dissolved as an additive, to prepare an electrolyte solution. Besides, for verifying the effect of the additive more clearly, here, an electrolyte layer 7 was composed only of the electrolyte solution, without using any porous film. In the same way as in Example 1 in other points than the just-mentioned, a dye-sensitized photoelectric conversion element was manufactured.

### Example 9

A dye-sensitized photoelectric conversion element was manufactured in the same manner as in Example 8, except that an electrolyte solution was prepared by use of 4-MeO-Py as an additive.

### Example 10

A dye-sensitized photoelectric conversion element was manufactured in the same manner as in Example 8, except that an electrolyte solution was prepared by use of 4-Et-Py as an additive.

### Example 11

A dye-sensitized photoelectric conversion element was manufactured in the same manner as in Example 8, except that an electrolyte solution was prepared by use of MIm as an additive.

### Example 12

A dye-sensitized photoelectric conversion element was manufactured in the same manner as in Example 8, except that an electrolyte solution was prepared by use of 24-Lu as an additive.

### Example 13

A dye-sensitized photoelectric conversion element was manufactured in the same manner as in Example 8, except that an electrolyte solution was prepared by use of 25-Lu as an additive.

### Example 14

A dye-sensitized photoelectric conversion element was manufactured in the same manner as in Example 8, except that an electrolyte solution was prepared by use of 26-Lu as an additive.

### Example 15

A dye-sensitized photoelectric conversion element was manufactured in the same manner as in Example 8, except that an electrolyte solution was prepared by use of 34-Lu as an additive.

### Example 16

A dye-sensitized photoelectric conversion element was manufactured in the same manner as in Example 8, except that an electrolyte solution was prepared by use of 35-Lu as an additive.

### Comparative Example 2

A dye-sensitized photoelectric conversion element was manufactured in the same manner as in Example 8, except that an electrolyte solution was prepared without using any additive.

### Comparative Example 3

A dye-sensitized photoelectric conversion element was manufactured in the same manner as in Example 8, except that an electrolyte solution was prepared by use of TBP as an additive.

### Comparative Example 4

A dye-sensitized photoelectric conversion element was manufactured in the same manner as in Example 8, except that an electrolyte solution was prepared by use of 4-picoline (4-pic) as an additive.

### Comparative Example 5

A dye-sensitized photoelectric conversion element was manufactured in the same manner as in Example 8, except that an electrolyte solution was prepared by use of methyl isonicotinate (4-COOMe-Py) as an additive.

### Comparative Example 6

A dye-sensitized photoelectric conversion element was manufactured in the same manner as in Example 8, except that an electrolyte solution was prepared by use of 4-cyanopyridine (4-CN-Py) as an additive.

### Comparative Example 7

A dye-sensitized photoelectric conversion element was manufactured in the same manner as in Example 8, except that an electrolyte solution was prepared by use of 4-aminopyridine (4-NH2-Py) as an additive.

### Comparative Example 8

A dye-sensitized photoelectric conversion element was manufactured in the same manner as in Example 8, except that an electrolyte solution was prepared by use of 4-(methylamino)pyridine (4-MeNH-Py) as an additive.

### Comparative Example 9

A dye-sensitized photoelectric conversion element was manufactured in the same manner as in Example 8, except that an electrolyte solution was prepared by use of 3-methoxypyridine (3-MeO-Py) as an additive.

### Comparative Example 10

A dye-sensitized photoelectric conversion element was manufactured in the same manner as in Example 8, except that an electrolyte solution was prepared by use of 2-methoxypyridine (2-MeO-Py) as an additive.

### Comparative Example 11

A dye-sensitized photoelectric conversion element was manufactured in the same manner as in Example 8, except that an electrolyte solution was prepared by use of methyl nicotinate (3-COOMe-Py) as an additive.

### Comparative Example 12

A dye-sensitized photoelectric conversion element was manufactured in the same manner as in Example 8, except that an electrolyte solution was prepared by use of pyridine (Py) as an additive.

### Comparative Example 13

A dye-sensitized photoelectric conversion element was manufactured in the same manner as in Example 8, except that an electrolyte solution was prepared by use of 3-bromopyridine (3-Br-Py) as an additive.

### Comparative Example 14

A dye-sensitized photoelectric conversion element was manufactured in the same manner as in Example 8, except that an electrolyte solution was prepared by use of N-methylbenzimidazole (NMB) as an additive.

### Comparative Example 15

A dye-sensitized photoelectric conversion element was manufactured in the same manner as in Example 8, except that an electrolyte solution was prepared by use of pyrazine as an additive.

### Comparative Example 16

A dye-sensitized photoelectric conversion element was manufactured in the same manner as in Example 8, except that an electrolyte solution was prepared by use of thiazole as an additive.

### Comparative Example 17

A dye-sensitized photoelectric conversion element was manufactured in the same manner as in Example 8, except that an electrolyte solution was prepared by use of N-methylpyrazole (Me-pyrazole) as an additive.

### Comparative Example 18

A dye-sensitized photoelectric conversion element was manufactured in the same manner as in Example 8, except that an electrolyte solution was prepared by use of quinoline as an additive.

### Comparative Example 19

A dye-sensitized photoelectric conversion element was manufactured in the same manner as in Example 8, except that an electrolyte solution was prepared by use of isoquinoline as an additive.

### Comparative Example 20

A dye-sensitized photoelectric conversion element was manufactured in the same manner as in Example 8, except that an electrolyte solution was prepared by use of 2,2′-bipyridyl (bpy) as an additive.

### Comparative Example 21

A dye-sensitized photoelectric conversion element was manufactured in the same manner as in Example 8, except that an electrolyte solution was prepared by use of pyridazine as an additive.

### Comparative Example 22

A dye-sensitized photoelectric conversion element was manufactured in the same manner as in Example 8, except that an electrolyte solution was prepared by use of pyrimidine as an additive.

### Comparative Example 23

A dye-sensitized photoelectric conversion element was manufactured in the same manner as in Example 8, except that an electrolyte solution was prepared by use of acridine as an additive.

### Comparative Example 24

A dye-sensitized photoelectric conversion element was manufactured in the same manner as in Example 8, except that an electrolyte solution was prepared by use of 5,6-benzoquinoline (56-benzoquinoline) as an additive.

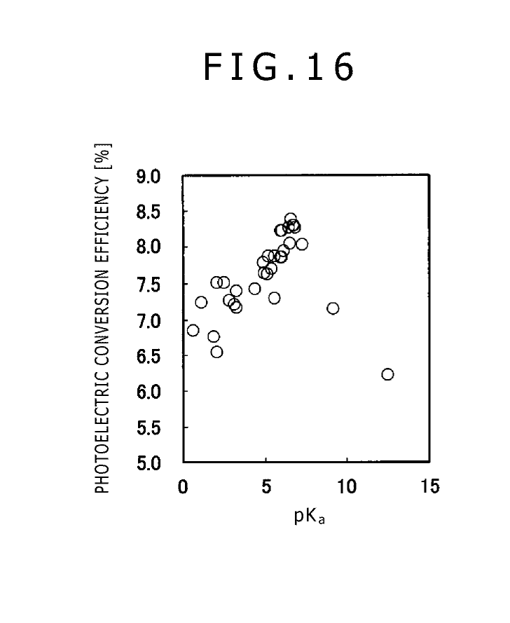

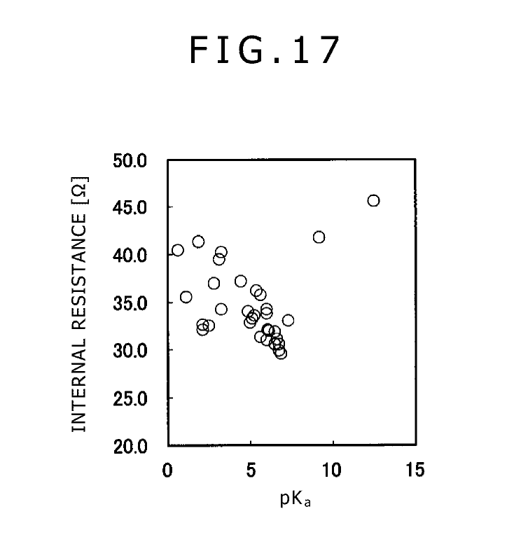

Table 4 shows the pKₐ (water), photoelectric conversion efficiency (Eff) and internal resistance (Rₛ) in Examples 8 to 10 and Comparative Examples 2 to 13 in each of which a pyridine additive was used. Table 5 shows the pKₐ (water), photoelectric conversion efficiency (Eff) and internal resistance (Rₛ) in Examples 11 to 16 and Comparative Example 14 to 24 in each of which an additive having a heterocyclic ring was used. From Tables 4 and 5, it is seen that, in each of Examples 8 to 16 in which an additive having a pKₐ in the range of 6.04≦pKₐ≦7.3 was used, the photoelectric conversion efficiency (Eff) was equivalent or higher and the internal resistance (Rₛ) was lower, as compared with Comparative Example 3 in which 4-tert-butylpyridine was used. FIG. 16 shows photoelectric conversion efficiency (Eff) plotted against pKₐ, for Examples 8-16 and Comparative Examples 2 to 24. Besides, FIG. 17 shows internal resistance (Rₛ) plotted against pKₐ, for Examples 8 to 16 and Comparative Examples 2 to 24.

TABLE 4

| | Additive | pKₐ(water) | Eff(%) | Rₛ(Ω) |
|---|---|---|---|---|
| Example 8 | 2-NH2—Py | 6.86 | 8.3 | 29.5 |
| Example 9 | 4-MeO—Py | 6.62 | 8.4 | 31.0 |
| Example 10 | 4-Et—Py | 6.04 | 8.2 | 32.1 |
| Comp. Ex. 2 | Nil | | 7.1 | 35.5 |
| Comp. Ex. 3 | TBP | 5.99 | 7.9 | 33.8 |
| Comp. Ex. 4 | 4-pic | 6.03 | 7.9 | 34.3 |
| Comp. Ex. 5 | 4-COOMe—Py | 3.26 | 7.2 | 40.2 |
| Comp. Ex. 6 | 4-CN—Py | 1.9 | 6.7 | 41.3 |
| Comp. Ex. 7 | 4-NH2—Py | 9.17 | 7.1 | 41.7 |
| Comp. Ex. 8 | 4-MeNH—Py | 12.5 | 6.2 | 45.6 |
| Comp. Ex. 9 | 3-MeO—Py | 4.88 | 7.8 | 34.0 |
| Comp. Ex. 10 | 2-MeO—Py | 3.28 | 7.4 | 34.3 |
| Comp. Ex. 11 | 3-COOMe—Py | 3.13 | 7.2 | 39.5 |
| Comp. Ex. 12 | Py | 5.23 | 7.9 | 33.6 |
| Comp. Ex. 13 | 3-Br—Py | 2.84 | 7.3 | 36.9 |

TABLE 5

| | Additive | pKₐ(water) | Eff(%) | Rₛ(Ω) |
|---|---|---|---|---|
| Example 11 | Mlm | 7.3 | 8.0 | 33.0 |
| Example 12 | 24-Lu | 6.72 | 8.3 | 29.9 |
| Example 13 | 25-Lu | 6.47 | 8.3 | 30.5 |
| Example 14 | 26-Lu | 6.77 | 8.3 | 30.6 |
| Example 15 | 34-Lu | 6.52 | 8.0 | 31.9 |
| Example 16 | 35-Lu | 6.14 | 7.9 | 32.0 |
| Comp. Ex. 14 | NMB | 5.6 | 7.9 | 35.8 |
| Comp. Ex. 15 | pyrazine | 0.6 | 6.8 | 40.4 |
| Comp. Ex. 16 | thiazole | 2.5 | 7.5 | 32.5 |
| Comp. Ex. 17 | Me-pyrazole | 2.1 | 7.5 | 32.7 |
| Comp. Ex. 18 | quinoline | 4.97 | 7.6 | 32.9 |
| Comp. Ex. 19 | isoquinoline | 5.38 | 7.7 | 36.1 |
| Comp. Ex. 20 | bpy | 4.42 | 7.4 | 37.2 |
| Comp. Ex. 21 | pyridazine | 2.1 | 6.5 | 32.0 |
| Comp. Ex. 22 | pyrimidine | 1.1 | 7.2 | 35.5 |
| Comp. Ex. 23 | acridine | 5.6 | 7.3 | 31.3 |
| Comp. Ex. 24 | 56-benzoquinoline | 5.15 | 7.6 | 33.3 |

Now, the dependency of the effect of the additive added to the electrolyte solution on the kind of solvent of the electrolyte solution will be described below.

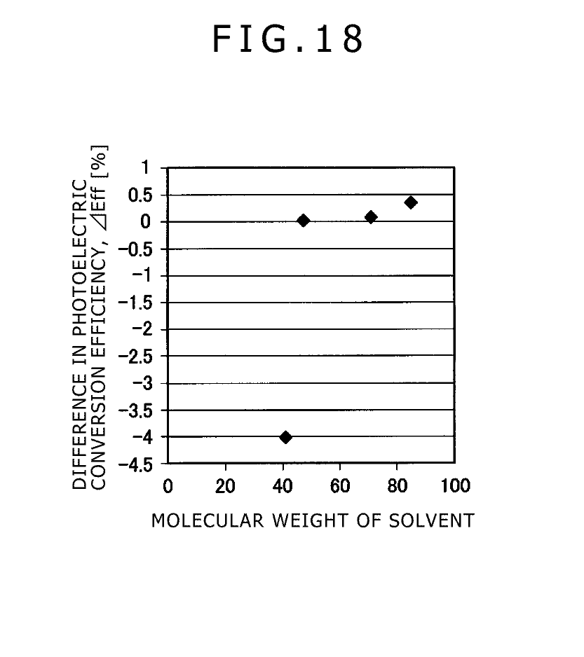

The effect of each additive was confirmed on the basis of each of the solvents differing in molecular weight. Here, 4-tert-butylpyridine (TBP) and 4-Et-Py (4-ethylpyridine), which have comparatively close pKₐ values, were made to be objects of comparison. The evaluation method is as follows. The photoelectric conversion efficiency (Eff(4-Et-Py)) of the dye-sensitized photoelectric conversion element using 4-Et-Py as an additive to the electrolyte solution and the photoelectric conversion efficiency (Eff(TBP)) of the dye-sensitized photoelectric conversion element using TBP as an additive to the electrolyte solution are measured, on the basis of each of the solvents. Then, the difference ΔEff=Eff(4-Et-Py)−Eff(TBP) between these photoelectric conversion efficiencies is used as an index of the effect. As the solvent of the electrolyte solution, four solvents consisting of acetonitrile (AN), a mixed liquid of acetonitrile (AN) and valeronitrile (VN), methoxyacetonitrile (MAN) and 3-methoxyropionitrile (MPN) were used. Table 6 shows molecular weight, Eff(4-Et-Py), Eff(TBP) and ΔEff, for each of the solvents. It is to be noted here that the values of Eff(4-Et-Py), Eff(TBP) and ΔEff for acetonitrile (AN) were obtained by reference to those reported in Solar Energy Materials & Solar Cells, 2003, 80, 167. FIG. 18 shows the difference in photoelectric conversion efficiency, ΔEff, plotted against the molecular weight of the solvents.

TABLE 6

| | Molecular | Eff | Eff | |
|---|---|---|---|---|
| Solvent | Weight | (4-Et—Py) | (TBP) | ΔEff |
| AN | 41.05 | 3.4 | 7.4 | −4 |
| AN/VN | 47.36 | 8.72 | 8.69 | 0.03 |
| MAN | 71.08 | 8.05 | 7.96 | 0.09 |
| MPN | 85.1 | 8.22 | 7.86 | 0.36 |

From Table 6 and FIG. 18, it is seen that the molecular weight range for ΔEff>0, in other words, the molecular weight range in which Eff(4-Et-Py) is greater than Eff(TBP), is not less than 47.36. It should be noted here that the value of 47.36 is an apparent molecular weight calculated by use of mixing volume fractions in the mixed liquid of acetonitrole (AN) and valeronitrile (VN).

As seen from the foregoing, it can be said that the use of an additive having a pKₐ in the range of 6.04≦pKₐ≦7.3 as the additive to the electrolyte solution is effective, in the cases of the solvents having molecular weights of not less than 47.36.

As above-mentioned, according to the third embodiment, an additive having a pKₐ in the range of 6.04≦pKₐ≦7.3 is used as the additive to the electrolyte solution contained in the porous film constituting the electrolyte layer 7, so that the following merits can be obtained in addition to the same merits as those obtained in the first embodiment above. An equivalent or higher photoelectric conversion efficiency and an equivalent or lower internal resistance can be obtained, as compared with the dye-sensitized photoelectric conversion element according to the related art in which 4-tert-butylpyridine is used as the additive to the electrolyte solution. Consequently, a dye-sensitized photoelectric conversion element having excellent photoelectric conversion characteristics can be obtained.

Besides, since there are a variety of additives which have a pKₐ in the range of 6.04≦pKₐ≦7.3, the choice of additive is extremely broad.

### 4. Fourth Embodiment

### Dye-Sensitized Photoelectric Conversion Element

A dye-sensitized photoelectric conversion element according to a fourth embodiment of the present disclosure differs from that according to the first embodiment above in that a solvent containing at least an ionic liquid having an electron-acceptive functional group and an organic solvent having an electron-donative functional group is used as solvent of an electrolyte solution contained in a porous film constituting an electrolyte layer 7.

Typically, the electron-acceptive functional group is possessed by a cation constituting the ionic liquid. The cation in the ionic liquid is preferably an organic cation which has an aromatic amine cation having a quaternary nitrogen atom and which has a hydrogen atom in the aromatic ring. Non-limitative examples of the organic cation include imidazolium cation, pyridinium cation, thiazolium cation, and pyrazonium cation. As the anion in the ionic liquid, there is preferably used an anion having a van der Waals volume of not less than 76 Å³, more preferably not less than 100 Å³.

Specific examples of the ionic liquid having an electron-acceptive functional group are as follows.

EMImTCB: 1-ethyl-3-methylimidazolium tetracyanoborate

EMImTFSI: 1-ethyl-3-methylimidazolium bis(trifluoromethanesulfon)amide.

EMImFAP: 1-ethyl-3-methylimidazolium tris(pentafluoroethyl)trifluorophosphate

EMImBF₄: 1-ethyl-3-methylimidazolium tetrafluoroborate

The organic solvent having the electron-donative functional group preferably has any of the following non-limitative chemical structures, from the viewpoint of lowering the evaporation rate.

Ether

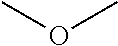

Ketone

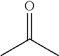

Amine structure

Primary amine

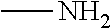

Tertiary amine

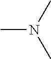

Aromatic amine

Pyridine structure

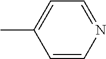

Imidazole structure

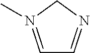

Sulfone

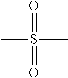

Sulfoxide

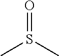

Specific examples of the organic solvent having an electron-donative functional group include the following.

MPN: 3-methoxypropionitrile

GBL: γ-butyrolactone

DMF: N,N-dimethylformamide

diglyme: diethylene glycol dimethyl ether

triglyme: triethylene glycol dimethyl ether

tetraglyme: tetraethylene glycol dimethyl ether

PhOAN: phenoxy acetonitrile

PC: propylene carbonate

aniline

DManiline: N,N-dimethylaniline

NBB: N-butylbenzimidazole

TBP: tert-butylpyridine

EMS: ethyl methyl sulfone

DMSO: dimethyl sulfoxide

Specific examples of the organic solvent having a tertiary nitrogen atom, classified into five kinds, include the following.

(1) methylamine, dimethylamine, trimethylamine, ethylamine, diethylamine, triethylamine, ethylmethylamine, n-propylamine, iso-propylamine, n-butylamine, sec-butylamine, tert-butylamine
(2) ethylenediamine
(3) aniline, N,N-dimethylaniline
(4) formamide, N-methylformamide, N,N-dimethylformamide, acetamide, N-methylacetamide, N,N-dimethylacetamide

### (5) N-methylpyrrolidone

When the compounds classified into (1) to (4) above are represented by a general formula, the compounds can be said to be organic molecules which have a molecular weight of not more than 1,000 and which have the following molecular skeleton.

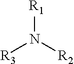

where R₁, R₂, and R₃ are each a substituent group selected from the group consisting of H, CₙHₘ (n=1 to 20, m=3 to 41), phenyl group, aldehyde group and acetyl group.

### [Method of Manufacturing Dye-Sensitized Photoelectric Conversion Element]

A method of manufacturing this dye-sensitized photoelectric conversion element is the same as the method of manufacturing the dye-sensitized photoelectric conversion element according to the first embodiment above, except that a solvent containing at least an ionic liquid having an electron-acceptive functional group and an organic solvent having an electron-donative functional group is used as solvent of an electrolyte solution contained in a porous film constituting an electrolyte layer 7.

### Example 17

In 2.0 g of a mixed solvent prepared by mixing EMImTCB and diglyme in a weight ratio of 1:1, 1.0 g of 1-propyl-3-methylimidazolium iodide and 0.10 g of iodine I₂ and 0.054 g of 2-NH2-Py as an additive were dissolved, to prepare an electrolyte solution. Besides, in order to more clearly verify the effect of the use of a solvent containing at least an ionic liquid having an electron-acceptive functional group and an organic solvent having an electron-donative functional group as the solvent of the electrolyte solution, an electrolyte layer 7 composed only of the electrolyte solution was used here, instead of an electrolyte layer 7 using a porous film.

### Example 18

A dye-sensitized photoelectric conversion element was manufactured in the same manner as in Example 17, except that an electrolyte solution was prepared by use of a mixed solvent prepared by mixing EMImTCB and triglyme in a weight ratio of 1:1 as a solvent.

### Example 19

A dye-sensitized photoelectric conversion element was manufactured in the same manner as in Example 17, except that an electrolyte solution was prepared by use of a mixed solvent prepared by mixing EMImTCB and tetraglyme in a weight ratio of 1:1 as a solvent.

### Example 20

A dye-sensitized photoelectric conversion element was manufactured in the same manner as in Example 17, except that an electrolyte solution was prepared by use of a mixed solvent prepared by mixing EMImTCB and MPN in a weight ratio of 1:1 as a solvent.

### Example 21

A dye-sensitized photoelectric conversion element was manufactured in the same manner as in Example 17, except that an electrolyte solution was prepared by use of a mixed solvent prepared by mixing EMImTCB and PhOAN in a weight ratio of 1:1 as a solvent.

### Example 22

A dye-sensitized photoelectric conversion element was manufactured in the same manner as in Example 17, except that an electrolyte solution was prepared by use of a mixed solvent prepared by mixing EMImTCB and GBL in a weight ratio of 1:1 as a solvent.

### Example 23

A dye-sensitized photoelectric conversion element was manufactured in the same manner as in Example 17, except that an electrolyte solution was prepared by use of a mixed solvent prepared by mixing EMImTCB and PC in a weight ratio of 1:1 as a solvent.

### Example 24

A dye-sensitized photoelectric conversion element was manufactured in the same manner as in Example 17, except that an electrolyte solution was prepared by use of a mixed solvent prepared by mixing EMImTCB and aniline in a weight ratio of 1:1 as a solvent.

### Example 25

A dye-sensitized photoelectric conversion element was manufactured in the same manner as in Example 17, except that an electrolyte solution was prepared by use of a mixed solvent prepared by mixing EMImTCB and DMF in a weight ratio of 1:1 as a solvent.

### Example 26

A dye-sensitized photoelectric conversion element was manufactured in the same manner as in Example 17, except that an electrolyte solution was prepared by use of a mixed solvent prepared by mixing EMImTCB and DManiline in a weight ratio of 1:1 as a solvent.

### Example 27

A dye-sensitized photoelectric conversion element was manufactured in the same manner as in Example 17, except that an electrolyte solution was prepared by use of a mixed solvent prepared by mixing EMImTCB and NBB in a weight ratio of 1:1 as a solvent.

### Example 28

A dye-sensitized photoelectric conversion element was manufactured in the same manner as in Example 17, except that an electrolyte solution was prepared by use of a mixed solvent prepared by mixing EMImTCB and TBP in a weight ratio of 1:1 as a solvent.

### Example 29

A dye-sensitized photoelectric conversion element was manufactured in the same manner as in Example 17, except that an electrolyte solution was prepared by use of a mixed solvent prepared by mixing EMImTFSI and triglyme in a weight ratio of 1:1 as a solvent.

### Example 30

A dye-sensitized photoelectric conversion element was manufactured in the same manner as in Example 17, except that an electrolyte solution was prepared by use of a mixed solvent prepared by mixing EMImFAP and triglyme in a weight ratio of 1:1 as a solvent.

### Example 31

A dye-sensitized photoelectric conversion element was manufactured in the same manner as in Example 17, except that an electrolyte solution was prepared by use of 1.0 g of 1-propyl-3-methylimidazolium iodide, 0.10 g of iodine I₂ and 0.054 g of N-butylbenzoimidazole (NBB) in 2.0 g of a mixed solvent prepared by mixing EMImCB and EMS in a weight ratio of 1:1 and serving as a solvent.

### Example 32

A dye-sensitized photoelectric conversion element was manufactured in the same manner as in Example 17, except that an electrolyte solution was prepared by use of 1.0 g of 1-propyl-3-methylimidazolium iodied, 0.1 g of iodine I₂ and 0.045 g of N-butylbenzoimidazole (NBB) in 2.0 g of a mixed solvent prepared by mixing EMImTCB and DMSO in a weight ratio of 1:1 and serving as a solvent.

### Comparative Example 25

A dye-sensitized photoelectric conversion element was manufactured in the same manner as in Example 17, except that an electrolyte solution was prepared by use of diglyme as a solvent.

### Comparative Example 26

A dye-sensitized photoelectric conversion element was manufactured in the same manner as in Example 17, except that an electrolyte solution was prepared by use of EMImTCB as a solvent.

### Comparative Example 27

A dye-sensitized photoelectric conversion element was manufactured in the same manner as in Example 17, except that an electrolyte solution was prepared by use of MPN as a solvent.

### Comparative Example 28

A dye-sensitized photoelectric conversion element was manufactured in the same manner as in Example 17, except that an electrolyte solution was prepared by use of a mixed solvent prepared by mixing EMImTCB and PhAN (phenyl acetonitrile) in a weight ratio of 1:1 as a solvent.

### Comparative Example 29

A dye-sensitized photoelectric conversion element was manufactured in the same manner as in Example 17, except that an electrolyte solution was prepared by use of a mixed solvent prepared by mixing EMImBF₄ (1-ethyl-3-methylimidazolium tetrafluoroborate) and triglyme in a weight ratio of 1:1 as a solvent.

### Comparative Example 30

A dye-sensitized photoelectric conversion element was manufactured in the same manner as in Example 17, except that an electrolyte solution was prepared by use of a mixed solvent prepared by mixing EMImOTf (1-ethyl-3-methylimidazolium trifluoromethanesulfonate) and triglyme in a weight ratio of 1:1 as a solvent.

### Comparative Example 31

A dye-sensitized photoelectric conversion element was manufactured in the same manner as in Example 17, except that an electrolyte solution was prepared by use of a mixed solvent prepared by mixing P₂₂₂MOMTFSI (triethyl(methoxymethyl)phosphonium bis(trifluoromethylsulfonyl)imide and triglyme in a weight ratio of 1:1 as a solvent.

### Comparative Example 32

A dye-sensitized photoelectric conversion element was manufactured in the same manner as in Example 17, except that an electrolyte solution was prepared by use of EMImTCB as a solvent.

Table 7 shows the results of determination of evaporation rate lowering ratio Zᵥₐₚₒᵣ, for the mixed solvent of the ionic liquid and the organic solvent, in each of Examples 17-32 and Comparative Examples 28-31. It is to be noted here that the weight ratio of the organic solvent in the mixed solvent is 50 wt %. The evaporation rate lowering ratio Zᵥₐₚₒᵣ is defined as Zᵥₐₚₒᵣ (%)=[1−(weight ratio of organic solvent in mixed solvent)×(kₘᵢₓₜᵤᵣₑ/kₙₑₐₜ)]×100, where kₙₑₐₜ is the evaporation rate of the organic solvent alone, and kₘᵢₓₜᵤᵣₑ is the evaporation rate of the mixed solvent of the ionic liquid and the organic solvent, both of which are determined by TG (Thermo Gravimetry)-DTA (Differential Thermal Analysis) measurement. A higher value of Zᵥₐₚₒᵣ indicates that the volatility of the organic solvent component in the mixed solvent is more lowered, as compared with the case where the organic solvent is used alone.

TABLE 7

| | Ionic | Organic | |
|---|---|---|---|
| | Liquid | Solvent | Zᵥₐₚₒᵣ |
| Example 17 | EMImTCB | diglyme | 50 |
| Example 18 | EMImTCB | triglyme | 59 |
| Example 19 | EMImTCB | tetraglyme | 78 |
| Example 20 | EMImTCB | MPN | 12 |
| Example 21 | EMImTCB | PhOAN | 11 |
| Example 22 | EMImTCB | GBL | 14 |
| Example 23 | EMImTCB | PC | 9 |
| Example 24 | EMImTCB | aniline | 31 |
| Example 25 | EMImTCB | DMF | 39 |
| Example 26 | EMImTCB | DManiline | 8 |
| Example 27 | EMImTCB | NBB | 8 |
| Example 28 | EMImTCB | TBP | 7 |
| Example 29 | EMImTFSI | triglyme | 37 |
| Example 30 | EMImFAP | triglyme | 25 |
| Example 31 | EMImTCB | EMS | 26 |
| Example 32 | EMImTCB | DMSO | 27.5 |
| Comp. Ex. 28 | EMImTCB | PhAN | 0 |
| Comp. Ex. 29 | EMImBF₄ | triglyme | −12 |
| Comp. Ex. 30 | EMImOTf | triglyme | −2 |
| Comp. Ex. 31 | P₂₂₂MOMTFSI | triglyme | −9 |

From Table 7 it is seen that in Examples 17 to 32, the value of Zᵥₐₚₒᵣ is a high positive value, indicating a lowering in volatility of the organic solvent component due to the mixing of the ionic liquid with the organic solvent. In contrast, in Comparative Examples 28 to 31, the value of Zᵥₐₚₒᵣ is 0 or negative, indicating that the volatility of the organic solvent component is not lowered by mixing of the ionic liquid with the organic solvent.

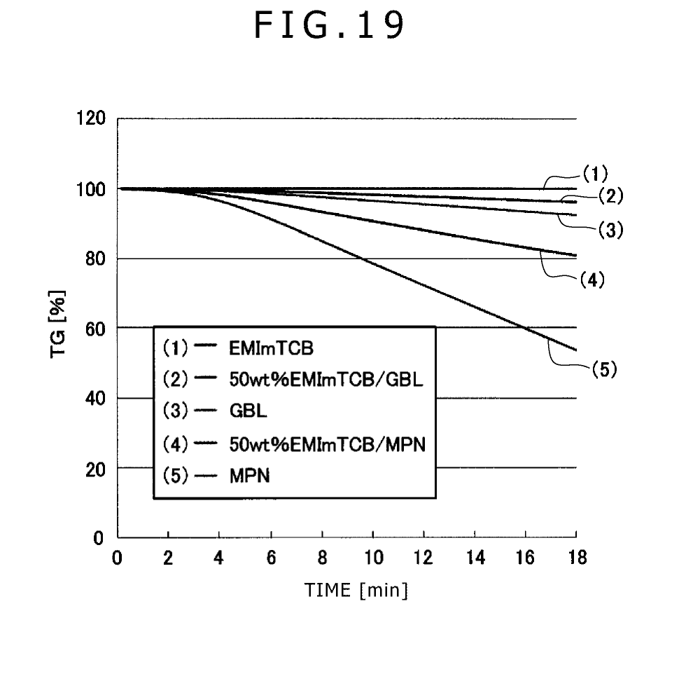

FIG. 19 shows TG-DTA curves of various solvents. As seen from FIG. 19, in the case where a mixed solvent of EMImTCB and MPN (the weight ratio of EMImTCB:50 wt %) is used (Example 20; curve (4)), the weight loss is much smaller, as compared with the case where MPN is used alone (Comparative Example 27; curve (5)). Besides, in the case where a mixed solvent of EMImTCB and GBL (the weight ratio of EMImTCB:50 wt %) is used (Example 22; curve (2)), the weight loss is smaller, as compared with the case where GBL is used alone (curve (3)).

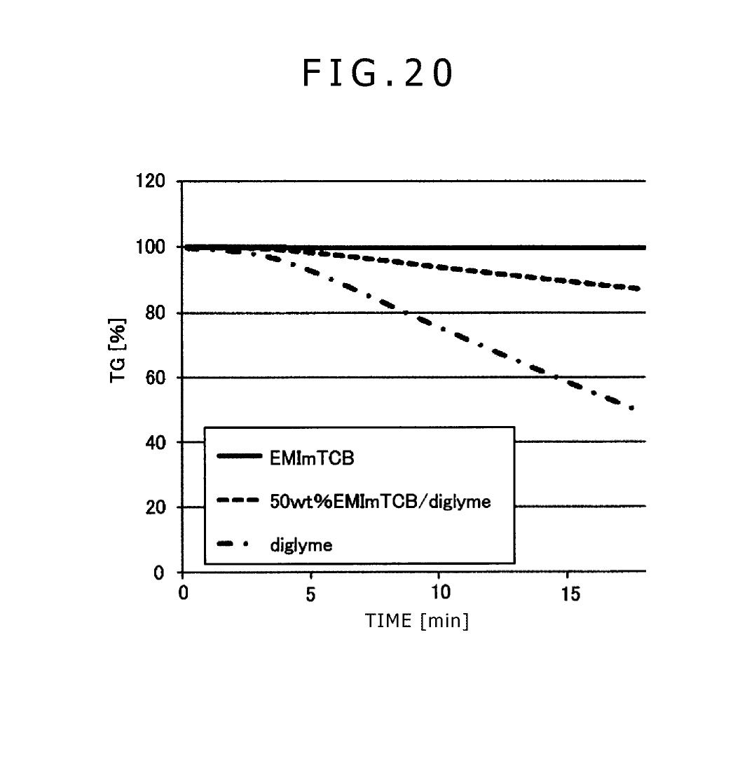

FIG. 20 shows TG-DTA curves, for the case where a mixed solvent of EMImTCB and diglyme (the weight ratio of EMImTCB:50 wt %) is used (Example 17), the case where EMImTCB is used alone, and the case where diglyme is used alone. From FIG. 20 it is seen that in the case where the mixed solvent of EMImTCB and diglyme is used, the weight loss is extremely small, as compared with the case of using diglyme alone, and the weight loss is suppressed to a level comparable to the level in the case of using EMImTCB alone.

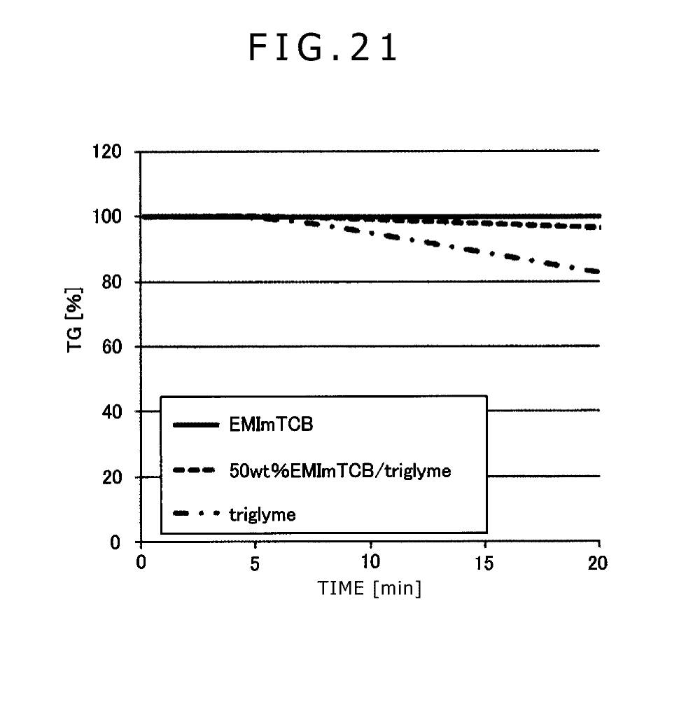

FIG. 21 shows TG-DTA curves, for the case where a mixed solvent of EMImTCB and triglyme (the weight ratio of EMImTCB:50 wt %) was used (Example 18), the case where EMImTCB was used alone, and the case where triglyme was used alone. It is seen from FIG. 21 that in the case where the mixed solvent of EMImTCB and triglyme is used, the weight loss is extremely small, as compared with the case of using triglyme alone, and the weight loss is suppressed to a level comparable to the level in the case of using EMImTCB alone.

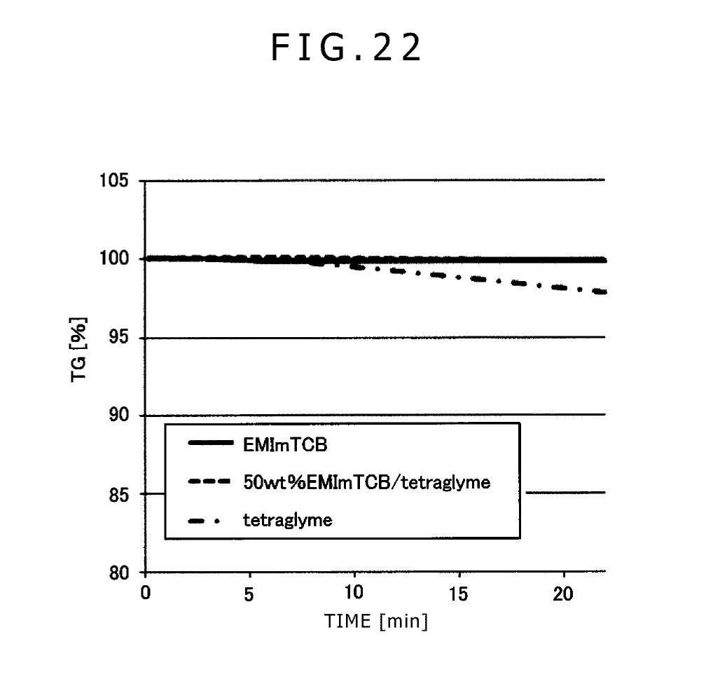

FIG. 22 shows TG-DTA curves, for the case where a mixed solvent of EMImTCB and tetraglyme (the weight ratio of EMImTCB:50 wt %) was used (Example 19), the case where EMImTCB was used alone, and the case where tetraglyme was used alone. From FIG. 22 it is seen that in the case where the mixed solvent of EMImTCB and tetraglyme is used, the weight loss is extremely small, as compared with the case of using tetraglyme alone, and, moreover, there is little weight loss, like in the case where EMImTCB is used alone.

The current-voltage characteristic of a dye-sensitized photoelectric conversion element was measured, for each of the case where a mixed solvent of EMImTCB and diglyme was used as the solvent of the electrolyte solution, the case where EMImTCB was used alone, and the case where diglyme was used alone. The measurement was carried out by irradiating each dye-sensitized photoelectric conversion element with pseudo-sunlight (artificial, or simulated, solar radiation) (AM 1.5, 100 mW/cm²). Table 8 shows open circuit voltage V_{oc}, current density J_{sc}, fill factor (FF) and photoelectric conversion efficiency, for the dye-sensitized photoelectric conversion elements.

TABLE 8

| | | | | Photoelectric |
|---|---|---|---|---|
| | | | | Conversion |
| | V_{oc} | J_{sc} | FF | Efficiency |
| Solvent | (V) | (mA/cm²) | (%) | (%) |
| EMImTCB | 0.737 | 12.60 | 67.1 | 6.23 |
| 50 wt % EMImTCB/diglyme | 0.732 | 13.92 | 67.1 | 6.83 |
| diglyme | 0.739 | 13.85 | 68.0 | 6.96 |

As seen from Table 8, the photoelectric conversion characteristics of the dye-sensitized photoelectric conversion element of Example 1 in which a mixed solvent of EMImTCB and diglyme was used as the solvent of the electrolyte solution are much better than the photoelectric conversion characteristics of the dye-sensitized photoelectric conversion element of Comparative Example 26 in which EMImTCB alone was used as the solvent of the electrolyte solution. The photoelectric conversion characteristics in Example 1 are comparable to those in the case where diglyme alone is used as the solvent of the electrolyte solution.

The current-voltage curve of the dye-sensitized photoelectric conversion element was measured, for each of the case where a mixed solvent of EMImTCB and MPN (the weight ratio of EMImTCB:22 wt %) was used as the solvent of the electrolyte solution, the case where a mixed solvent of EMImTFSI and MPN (the weight ratio of EMImTFSI:35 wt %) was used, and the case where MPN alone was used. The measurement was carried out by irradiating the dye-sensitized photoelectric conversion element with pseudo-sunlight (artificial, or simulated, solar radiation) (AM 1.5, 100 mW/cm²). Table 9 shows open circuit voltage V_{oc}, current density J_{sc}, fill factor (FF) and photoelectric conversion efficiency, for the dye-sensitized photoelectric conversion elements.

TABLE 9

| | | | | Photoelectric |
|---|---|---|---|---|
| | | | | Conversion |
| | V_{oc} | J_{sc} | FF | Efficiency |
| Solvent | (V) | (mA/cm²) | (%) | (%) |
| MPN | 0.71 | 15.7 | 63 | 7.0 |
| 22 wt % EMImTCB/MPN | 0.73 | 14.8 | 65 | 7.0 |
| 35 wt % EMImTFSI/MPN | 0.72 | 14.9 | 65 | 7.0 |

From Table 9 it is seen that both the dye-sensitized photoelectric conversion element using a mixed solvent of EMImTCB and MPN as the solvent of the electrolyte solution and the dye-sensitized photoelectric conversion element using a mixed solvent of EMImTFSI and MPN as the solvent of the electrolyte solution show photoelectric conversion characteristics comparable to those of the dye-sensitized photoelectric conversion element using MPN alone as the solvent of the electrolyte solution. Here, it is seen that in the cases of the dye-sensitized photoelectric conversion element where a mixed solvent is used as the solvent of the electrolyte solution, J_{sc} is lowered and V_{oc} is raised, as compared with the case where MPN alone is used as the solvent of the electrolyte solution. The lowering in J_{sc} is considered to be due to a lowering in diffusivity of the redox pair in the electrolyte solution, which is caused by the mixing of the ionic liquid. On the other hand, the rise in V_{oc} is considered to be due to a change in the electron potential of titanium oxide by pseudo-adsorption of the ionic liquid on the surfaces of the porous photoelectrode formed of titanium oxide, or due to a change in oxidation-reduction potential which is caused by an interaction with the redox pair.

Current-voltage curve was measured for the dye-sensitized photoelectric conversion element of Example 31 in which a mixed solvent of EMImTCB and EMS (the weight ratio of EMImTCB:50 wt %) was used as the solvent of the electrolyte solution. Also, current-voltage curve was measured for the dye-sensitized photoelectric conversion element of Comparative Example 33 in which EMImTCB alone was used as the solvent of the electrolyte solution. The measurement was carried out by irradiating the dye-sensitized photoelectric conversion element with pseudo-sunlight (artificial, or simulated, solar radiation) (AM 1.5, 100 mW/cm²). Table 10 shows open circuit voltage V_{oc}, current density J_{sc}, fill factor (FF) and photoelectric conversion efficiency, for the dye-sensitized photoelectric conversion elements.

TABLE 10

| | | | | Photoelectric |
|---|---|---|---|---|
| | | | | Conversion |
| | V_{oc} | J_{sc} | FF | Efficiency |
| Solvent | (V) | (mA/cm²) | (%) | (%) |
| EMImTCB | 0.667 | 11.94 | 72.6 | 5.78 |
| 50 wt % EMImTCB/EMS | 0.666 | 14.09 | 71.8 | 6.73 |

From Table 10 it is seen that the dye-sensitized photoelectric conversion element of Example 31 in which a mixed solvent of EMImCB and EMS was used as the solvent of the electrolyte solution is higher in photoelectric conversion efficiency by about 1% and higher in J_{sc} by about 2 mA/cm², than the dye-sensitized photoelectric conversion element of Comparative Example 33 in which EMImTCB alone was used as the solvent of the electrolyte solution. The increase in J_{sc} is attributable to a lowering in the viscosity coefficient of the electrolyte solution.

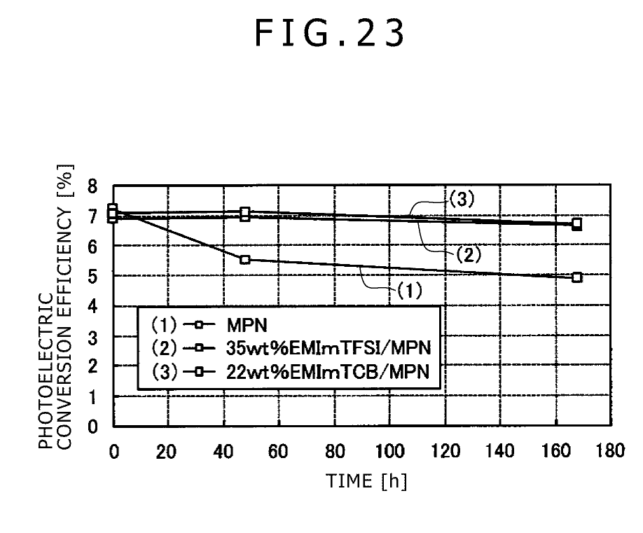

FIG. 23 shows the results of an acceleration test of the dye-sensitized photoelectric conversion element, for the case where a mixed solvent of EMImTCB and MPN (the weight ratio of EMImTCB:22 wt %) was used, the case where a mixed solvent of EMImTFSI and MPN (the weight ratio of EMImTFSI:35 wt %) was used, and the case where MPN alone was used, as the solvent of the electrolyte solution. In FIG. 23, the axis of abscissas represents holding time at 85° C., and the axis of ordinates represents photoelectric conversion efficiency. The test was carried out in a dark place where the dye-sensitized photoelectric conversion element was held at 85° C.

From FIG. 23 it is seen that in the case of the dye-sensitized photoelectric conversion element using MPN alone as the solvent of the electrolyte solution, the photoelectric conversion efficiency continued to decrease from the start of the test, and its value after 170 hours was lower than the initial value by no less than 30%. On the other hand, in the case of the dye-sensitized photoelectric conversion element using a mixed solvent of EMImTCB and MPN (the weight ratio of EMImTCB:22 wt %) as the solvent of the electrolyte solution and in the case of the dye-sensitized photoelectric conversion element using a mixed solvent of EMImTFSI and MPN (the weight ratio of EMImTFSI:35 wt %) as the solvent of the electrolyte solution, the lowering in the photoelectric conversion efficiency was little, even after the lapse of 170 hours from the start of the test, indicating high durability of the dye-sensitized photoelectric conversion elements. This is considered to be attributable to a lowering in volatility by an interaction of the ionic liquid molecules with the organic solvent molecules, and to stabilization by interactions of the ionic liquid molecules with the electrolyte solution component-electrode interface.

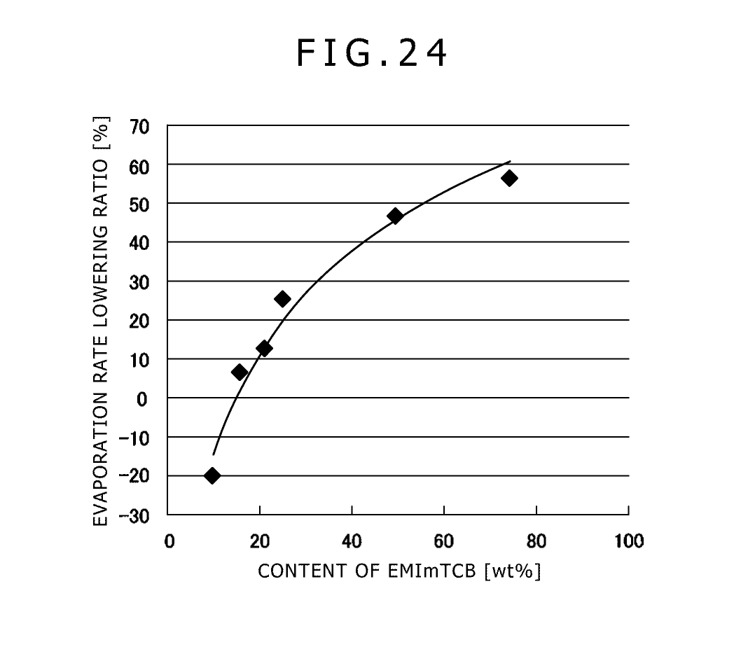

FIG. 24 shows the examination results of the relationship between the content of EMImTCB in a mixed solvent of EMImTCB and diglyme and evaporation rate lowering ratio, in the case where the mixed solvent is used as the solvent of the electrolyte solution. From FIG. 24, it is seen that a lowering in evaporation rate is observed when the content of EMImTCB is not less than 15 wt %.

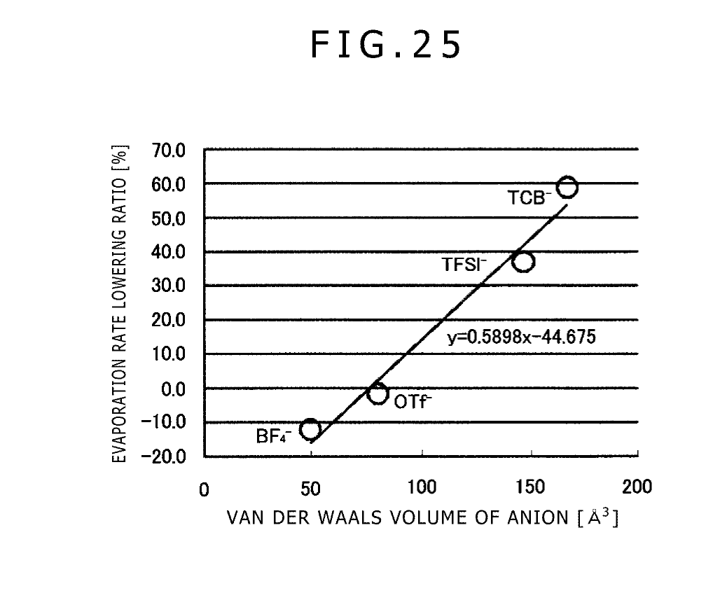

Now, preferable cation and anion structures in the ionic liquid will be described below. First, the cation is preferably an organic cation which has an aromatic amine cation having a quaternary nitrogen atom and which has a hydrogen atom in an aromatic ring. Examples of such an organic cation include imidazolium cation, pyridinium cation, thiazolium cation, and pyrazonium cation. As for the anion, the preferable structure can be defined by van der Waals volume (size of electron cloud) of the anion computed on a computational science basis. FIG. 25 shows vaporization rate lowering ratio plotted against van der Waals volume, for a few anions (TCB⁻, TFSI⁻, OTf⁻ and BF₄⁻). The values of van der Waals volume of the anions are obtained by reference to Journal of The Electrochemical Society 002, 149(10), A1385-A1388 (2002). As the van der Waals volume of the TCB anion, the van der Waals volume of (C₂H₅)₄B⁻ anion similar in structure to the TCB anion was used. Fitting of the data to a linear function was conducted. The fitting expression is y=0.5898x−44.675, where x is van der Waals volume, and y is evaporation rate lowering ratio. From FIG. 25, it is considered that a lowering in evaporation rate occurs in the cases of anions having a van der Waals volume of not less than 76 Å³, preferably not less than 100 Å³.

Now, the results of discussion on the principle of lowering in evaporation rate, in the case of a mixed solvent of an ionic liquid having an electron-acceptive functional group and an organic solvent having an electron-donative functional group, will be described below.

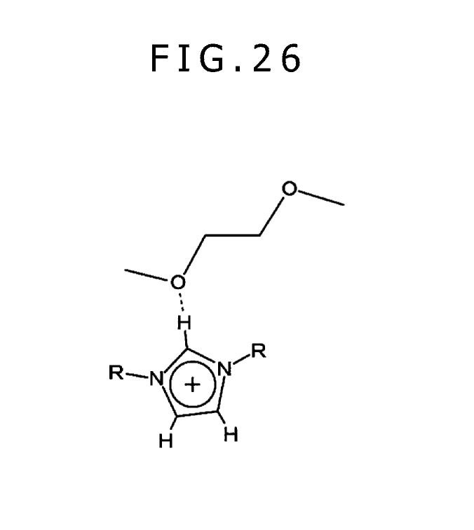

In the mixed solvent, a hydrogen bond is formed between the electron-acceptive functional group possessed by the ionic liquid and the electron-donative functional group (ether group, amino group, or the like) possessed by the organic solvent, resulting in stabilization on a thermal basis. FIG. 26 illustrates an example of this process. In this example, as shown in FIG. 26, a hydrogen bond (indicated by broken line) is formed between the electron-acceptive functional group (acidic proton) of the imidazolium cation in an ionic liquid and the ether group (—O—) of the diglyme molecule. Thus, it can be considered that, in this mixed solvent, hydrogen bonds are formed between the ionic liquid and the organic solvent, whereby thermal stabilization is effected, so that the evaporation rate is lowered.

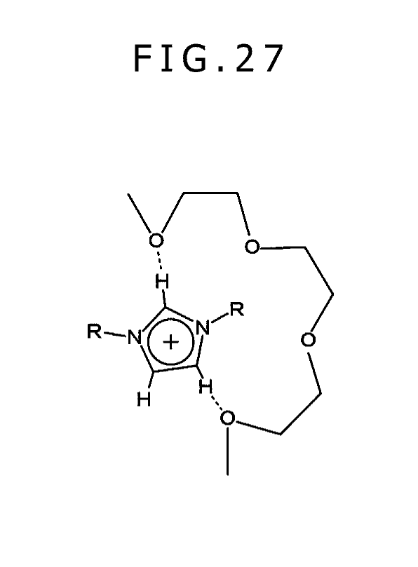

Especially, as the number of electron-donative functional groups in one molecule of the organic liquid increases, the evaporation rate lowering ratio increases. For instance, FIG. 27 shows an example in which the organic solvent is triglyme. In this example, hydrogen bonds are respectively formed between the two electron-acceptive functional groups (acidic protons) of the imidazolium cation in the ionic liquid and the two ethergroups of triglyme, whereby thermal stabilization is effected. Besides, in this case, when a hydrogen bond is formed between one electron-acceptive functional group of the imidazolium cation in the ionic liquid and one ether group of triglyme, another ether group of triglyme is brought close to another electron-acceptive functional group of the imidazolium cation in the ionic liquid. In other words, triglyme embraces the imidazolium cation. Consequently, the another electron-acceptive functional group of the imidazolium cation in the ionic liquid and the another ether group of triglyme interact with each other more easily, so that a hydrogen bond is easily formed between these functional groups.

Thus, according to the fourth embodiment, a mixed solvent of an ionic liquid having an electron-acceptive functional group and an organic solvent having an electron-donative functional group is used as the solvent of the electrolyte solution contained in the porous film constituting the electrolyte layer 7. Therefore, it is possible to obtain a merit that volatilization of the electrolyte solution can be restrained effectively and that, due to the lower viscosity coefficient of the mixed solvent, the viscosity coefficient of the electrolyte solution can be lowered, in addition to the same merits as those obtained in the first embodiment.

### 5. Fifth Embodiment

### Dye-Sensitized Photoelectric Conversion Element

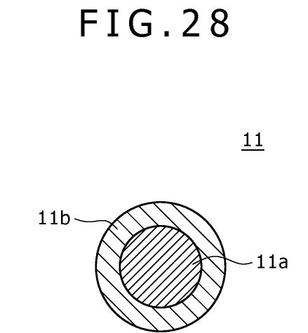

In a dye-sensitized photoelectric conversion element according to a fifth embodiment of the present disclosure, a porous photoelectrode 13 has metal/metallic oxide particulates, typically, a sintered body of metal/metallic oxide particulates. FIG. 28 shows in detail the structure of the metal/metallic oxide particulate 11. As shown in FIG. 28, the metal/metallic oxide particulate 11 has a core/shell structure which includes a spherical core 11a having a metal and a shell 11b having a metallic oxide surrounding the core 11a. One or more photosensitizing dyes (not shown) are bonded to (or adsorbed on) the surfaces of the metallic oxide shells 11b of the metal/metallic oxide particulates 11.

Examples of the metallic oxide constituting the shells 11b of the metal/metallic oxide particulates 11 include titanium oxide (TiO₂), tin oxide (SnO₂), niobium oxide (Nb₂O₅), and zinc oxide (ZnO). Among these metallic oxides, preferred is TiO₂, particularly, anatase-type TiO₂. It is to be noted here that the metallic oxide is not restricted to the just-mentioned ones, and two or more of the metallic oxides may be used as a mixture or a composite material, as required. In addition, the form of the metal/metallic oxide particulates 11 may be any of granular form, tubular form, rod-like form, and the like.

The particle diameter of the metal/metallic oxide particulates 11 is not particularly limited. Normally, the particle diameter in terms of average particle diameter of primary particles is 1 to 500 nm, preferably 1 to 200 nm, particularly preferably 5 to 100 nm. Besides, the particle diameter of the cores 11a of the metal/metallic oxide particulates 11 is normally 1 to 200 nm.

Other configurations of the dye-sensitized photoelectric conversion element than the above-mentioned are the same as in the first embodiment.

### [Method of Manufacturing Dye-Sensitized Photoelectric Conversion Element]

A method of manufacturing the dye-sensitized photoelectric conversion element is the same as the method of manufacturing the dye-sensitized photoelectric conversion element according to the first embodiment, except that a porous photoelectrode 3 is formed to have the metal/metallic oxide particulates 11.

The metal/metallic oxide particulates 11 constituting the porous photoelectrode 3 can be prepared by a known method (see, for example, Jpn. J. Appl. Phys., Vol. 46, No. 4B, 2007, pp. 2567-2570). As an example, a method of producing metal/metallic oxide particulates 11 in which the core 11a has Au and the shell 11b has TiO₂ will be outlined as follows. First, dehydrated trisodium citrate is added to 500 mL of heated 5×10⁻⁴ M HAuCl₄ solution, followed by stirring. Next, mercaptoundecanoic acid is added to an aqueous ammonia solution in an amount of 2.5 wt %, followed by stirring, then the resulting solution is added to the Au nanoparticle dispersion, and the admixture is warmed for 2 hours. Subsequently, 1 M HCl is added to the resulting solution, to adjust the pH to 3. Next, titanium isopropoxide and triethanolamine are added to the Au colloidal solution in a nitrogen atmosphere. In this manner, the metal/metallic oxide particulates 11 in which the core 11a has Au and the shell 11b has TiO₂ are prepared.

### [Operation of Dye-Sensitized Photoelectric Conversion Element]

Now, operation of the dye-sensitized photoelectric conversion element will be described below.

The dye-sensitized photoelectric conversion element, upon incidence of light thereon, operates as a cell with the counter electrode 6 as a positive electrode and with the transparent electrode 2 as a negative electrode. The principle of the operation is as follows. Incidentally, here, it is assumed that FTO is used as material for the transparent electrode 2, Au is used as material for the cores 11a of the metal/metallic oxide particulates 11 constituting the porous photoelectrode 3, while TiO₂ is used as material for the shells 11b of the metal/metallic oxide particulates 11, and oxidation-reduction species of I⁻/I₃⁻ are used as the redox pair. It should be noted, however, that the configurations thus assumed are not limitative.

When photons transmitted through the transparent substrate 1 and the transparent electrode 2 and incident on the porous photoelectrode 3 are absorbed by the photosensizing dye(s) bonded to the porous photoelectrode 3, electrons in the photosensitizing dye(s) are excited from the ground state (HOMO) to the excited state (LUMO). The electrons thus excited are drawn through the electrical bonding between the photosensitizing dye(s) and the porous photoelectrode 3 into the conduction band of TiO₂ constituting the shells 11b of the metal/metallic oxide particulates 11 constituting the porous photoelectrode 3, and pass through the porous photoelectrode 3, to reach the transparent electrode 2. In addition, light is incident on the surfaces of the Au cores 11a of the metal/metallic oxide particulates 11, whereby localized surface plasmon is excited, to produce a field intensifying effect. By the field intensification, a large amount of electrons are excited into the conduction band of TiO₂ constituting the shells 11b, and the electrons pass through the porous photoelectrode 3, to reach the transparent electrode 2. Thus, when light is incident on the porous photoelectrode 3, not only the electrons generated by excitation of the photosensitizing dye(s) reach the transparent electrode 2, but also the electrons excited into the conduction band of TiO₂ constituting the shells lib by excitation of the localized surface plasmon at the surfaces of the cores 11a of the metal/metallic oxide particulates 11 reach the transparent electrode 2. Consequently, a high photoelectric conversion efficiency can be obtained.

On the other hand, the photosensitizing dye(s) having lost the electrons accept electrons from a reducing agent, for example, I⁻ present in the electrolyte layer 7 through the following reaction, and produce an oxidizing agent, for example, I₃⁻ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above-mentioned, and is thereby reduced to the original reducing agent.

I₃⁻→I₂+I⁻

I₂+2e⁻→2I⁻

The electrons sent from the transparent electrode 2 to an external circuit perform an electrical work in the external circuit, and thereafter return to the counter electrode 6. In this manner, optical energy is converted into electrical energy, without leaving any change in the photosensitizing dye or in the electrolyte layer 7.

According to the fifth embodiment, the following merit can be obtained in addition to the same merits as those obtained in the first embodiment above. The porous photoelectrode 3 has the metal/metallic oxide particulates 11 having the core/shell structure which includes the spherical core 11a having a metal and the shell 11b having a metallic oxide surrounding the core 11a. Therefore, when the space between the porous photoelectrode 3 and the counter electrode 6 is filled with the electrolyte layer 7, the electrolyte of the electrolyte layer 7 does not make contact with the metal cores 11a of the metal/metallic oxide particulates 11, so that the porous photoelectrode 11 can be prevented from being dissolved by the electrolyte. Accordingly, metals having a high surface plasmon effect, such as gold, silver, copper, etc. can be used as the metal constituting the cores 11a of the metal/metallic oxide particulates 11, whereby the surface plasmon resonance effect can be sufficiently obtained. In addition, an iodine electrolyte can be used as the electrolyte of the electrolyte layer 7. Consequently, it is possible to obtain a dye-sensitized photoelectric conversion element having a high photoelectric conversion efficiency. Then, by use of the excellent dye-sensitized photoelectric conversion element, it is possible to realize a high-performance electronic apparatus.

### 6. Sixth Embodiment

### Photoelectric Conversion Element

A photoelectric conversion element according to a sixth embodiment of the present disclosure as the same configuration as the dye-sensitized photoelectric conversion element according to the fifth embodiment, except that no photosensitizing dye is bonded to metal/metallic oxide particulates 11 constituting a porous photoelectrode 3.

### [Method of Manufacturing Photoelectric Conversion Element]

A method of manufacturing this photoelectric conversion element is the same as the method of manufacturing the dye-sensitized photoelectric conversion element according to the fifth embodiment above, except that no photosensitizing dye is adsorbed on the porous photoelectrode 3.

### [Operation of Photoelectric Conversion Element]

Now, operation of this photoelectric conversion element will be described below.

The photoelectric conversion element, upon incidence of light thereon, operates as a cell with the counter electrode 6 as a positive electrode and with the transparent electrode 2 as a negative electrode. The principle of the operation is as follows. Incidentally, here, it is assumed that FTO is used as the material for the transparent electrode 2, Au is used as the material for the cores 11a of the metal/metallic oxide particulates 11 constituting the porous photoelectrode 3, while TiO₂ is used as the material for the shells 11b of the metal/metallic oxide particulates 11, and oxidation-reduction species of I⁻/I₃⁻ are used as the redox pair. It should be noted, however, that the configurations thus assumed are not limitative.

When light transmitted through the transparent substrate 1 and the transparent electrode 2 is incident on the surfaces of the Au cores 11a of the metal/metallic oxide particulates 11 constituting the porous photoelectrode 3, the localized surface plasmon is excited, whereby a field intensifying effect is obtained. By the field intensification, a large amount of electrons is excited into the conduction band of TiO₂ constituting the shells 11b, and the electrons pass through the porous photoelectrode 11, to reach the transparent electrode 2.

On the other hand, the porous photoelectrode 3 having lost the electrons accepts electrons from a reducing agent, for example, I⁻ present in the electrolyte layer 7 through the following reaction, and produce an oxidizing agent, for example, I₃⁻ (a coupled body of I₂ and I⁻) in the electrolyte layer 7.

2I⁻→I₂+2e⁻

I₂+I⁻→I₃⁻

The thus produced oxidizing agent diffuses to reach the counter electrode 6, where it accepts electrons from the counter electrode 6 through a reaction reverse to the above-mentioned, and is thereby reduced to the original reducing agent.

I₃⁻→I₂+I⁻

I₂+2e⁻→2I⁻

The electrons sent from the transparent electrode 2 to an external circuit perform an electrical work in the external circuit, and thereafter return to the counter electrode 6. In this manner, optical energy is converted into electrical energy, without leaving any change in the electrolyte layer 7.

According to the sixth embodiment, the same merits as those obtained in the first embodiment can be obtained.

While some embodiments and some Examples of the present disclosure have been specifically described above, the present disclosure is not to be limited to the embodiments and the Examples, and various modifications are possible based on the technical thought of the present disclosure.

For instance, the numerical values, structures, configurations, shapes, materials, etc. mentioned in the embodiments and Examples above are merely examples, so that numerical values, structures, configurations, shapes, materials, etc. different from the above-mentioned may also be adopted, as required.

The present application contains subject matter related to that disclosed in Japanese Priority Patent Application JP 2010-229333 filed in the Japan Patent Office on Oct. 12, 2010, the entire content of which is hereby incorporated by reference.

What is claimed is:

1. A photoelectric conversion element having a structure in which an electrolyte layer composed of a porous film containing an electrolyte solution is provided between a porous photoelectrode and a counter electrode.

2. The photoelectric conversion element according to claim 1, wherein the porous film has a non-woven fabric.

3. The photoelectric conversion element according to claim 2, wherein the non-woven fabric has polyolefin, polyester or cellulose.

4. The photoelectric conversion element according to claim 3, wherein the porous film has a porosity of not less than 80% and less than 100%.

5. The photoelectric conversion element according to claim 4, wherein the electrolyte is an ionic liquid electrolyte solution.

6. The photoelectric conversion element according to claim 1, wherein an additive having a pKₐ in the range of 6.04≦pKₐ≦7.3 is added to the electrolyte solution and/or an additive having a pKₐ in the range of 6.04≦pKₐ≦7.3 is adsorbed on that surface of at least one of the porous photoelectrode and the counter electrode which faces the electrolyte layer.

7. The photoelectric conversion element according to claim 6, wherein the additive is a pyridine additive or an additive having a heterocyclic ring.

8. The photoelectric conversion element according to claim 7, wherein the additive is one or more selected from the group consisting of 2-aminopyridine, 4-methoxypyridine, 4-ethylpyridine, N-methylimidazole, 2,4-lutidine, 2,5-lutidine, 2,6-lutidine, 3,4-lutidine, and 3,5-lutidine.

9. The photoelectric conversion element according to claim 6, wherein a solvent of the electrolyte solution has a molecular weight of not less than 47.3.

10. The photoelectric conversion element according to claim 9, wherein the solvent is 3-methoxypropionitrile, methoxyacetonitrile, or a mixed liquid of acetonitrile and valeronitrile.

11. The photoelectric conversion element according to claim 1, wherein the photoelectric conversion element is a dye-sensitized photoelectric conversion element having a photosensitizing dye bonded to the porous photoelectrode.

12. The photoelectric conversion element according to claim 11, wherein the porous photoelectrode is composed of particulates having a semiconductor.

13. The photoelectric conversion element according to claim 1, wherein a solvent of the electrolyte solution contains an ionic liquid having an electron-acceptive functional group and an organic solvent having an electron-donative functional group.

14. The photoelectric conversion element according to claim 1, wherein the porous photoelectrode is composed of particulates each of which includes a core having a metal and a shell having a metallic oxide surrounding the core.

15. A method of manufacturing a photoelectric conversion element, comprising:
disposing a porous film on one of a porous photoelectrode and a counter electrode; and
disposing the other of the porous photoelectrode and the counter electrode on the porous film.

16. The method of manufacturing the photoelectric conversion element according to claim 15, wherein the porous film contains an electrolyte solution, and the porous film containing the electrolyte solution constitutes an electrolyte layer.

17. The method of manufacturing the photoelectric conversion element according to claim 15, wherein after the porous film is disposed on the porous photoelectrode, the counter electrode is disposed on the porous film.

18. The method of manufacturing the photoelectric conversion element according to claim 17, further comprising
compressing the porous film after the porous film is disposed on the porous photoelectrode and before the counter electrode is disposed on the porous film.

19. An electrolyte layer for a photoelectric conversion element, comprising
a porous film which contains an electrolyte solution.

20. An electronic apparatus comprising
at least a photoelectric conversion element,
wherein the photoelectric conversion element has
a structure in which an electrolyte layer having a porous film containing an electrolyte solution is provided between a porous photoelectrode and a counter electrode.
